(19) United States
(12) Patent Application Publication
(10) Pub. No.: US 2025/0201792 A1
(43) Pub. Date: Jun. 19, 2025

(54) DATA AND POWER ISOLATION

(71) Applicant: TEXAS INSTRUMENTS INCORPORATED, Dallas, TX (US)

(72) Inventors: Nicola Bertoni, Freising (DE); Giacomo Calabrese, Freising (DE); Usama Anwar, Brooklyn, NY (US)

(21) Appl. No.: 18/542,564

(22) Filed: Dec. 15, 2023

(51) Int. Cl. H01L 25/18; H01F 27/28; H01L 23/00; H01L 23/538; H01L 27/01

(52) U.S. Cl. CPC H01L 25/18; H01F 27/2804; H01L 23/5386; H01L 24/14; H01L 24/16; H10D 86/85; H01F 2027/2809; H01L 2224/14519; H01L 2224/16145

(57) ABSTRACT

A packaged IC includes a package substrate including first and second metal planes on first and second sides, respectively, the second side opposing the first side, and a transformer laterally between the first and second metal planes, the transformer including a primary winding and a secondary winding, the primary winding includes outer primary-coil portions having first and second primary side terminals and an inner primary-coil portion, and the secondary winding includes outer secondary-coil portions having first and second secondary terminals and an inner secondary-coil portion. The packaged IC includes first and second dies on the first and second sides, respectively; first metal posts coupled between the first die and respective overlapping parts of the first metal plane, the primary terminals, and the inner primary-coil portion; and second metal posts coupled between the second die and respective overlapping parts of the second metal plane, the secondary terminals, and the inner secondary-coil portion.

### CROSS-REFERENCE TO RELATED APPLICATION

This application is related to U.S. application Ser. No. 18/542,381 filed Dec. 15, 2023, which claims the benefit of and priority to U.S. application Ser. No. 17/167,753, filed Feb. 4, 2021, which claims the benefit of and priority to U.S. Provisional Patent Application No. 62/976,427, filed Feb. 14, 2020, and U.S. Provisional Patent Application No. 63/131,407, filed Dec. 29, 2020, which are hereby fully incorporated herein by reference.

### BACKGROUND

Isolation is often desirable for interconnecting electrical systems to exchange data or power between the systems. For example, two systems may be powered by different supply sources that do not share a common ground connection. The two systems may be electrically isolated to prevent current and voltages in one system from negatively impacting the other system, for instance by damaging or interfering with the operation of one or more components of the other system. In some applications that use isolation circuits, challenges may arise with respect to size of the isolation circuit, maintaining voltage isolation, interconnection parasitics, thermal management, and isolation circuit efficiency.

### SUMMARY

Described is a packaged integrated circuit comprising a package substrate including a first metal plane on a first side, a second metal plane on a second side opposing the first side, and a transformer laterally between the first and second metal planes. In at least one example, the transformer includes a primary winding and a secondary winding, the primary winding includes outer primary coil portions having first and second primary side terminals and an inner primary coil portion, and the secondary winding includes outer secondary coil portions having first and second secondary side terminals and an inner secondary coil portion. In at least one example, the packaged integrated circuit comprises a first semiconductor die on the first side of the package substrate and overlapping at least parts of the outer primary coil portions, the inner primary coil portion, and the first metal plane. In at least one example, the packaged integrated circuit comprises a second semiconductor die on the second side of the package substrate and overlapping at least parts of the outer secondary coil portions, the inner secondary coil portion, and the second metal plane. In at least one example, the packaged integrated circuit comprises first metal posts coupled between the first semiconductor die and the respective overlapping parts of the first metal plane, the primary side terminals, and the inner primary coil portion. In at least one example, the packaged integrated circuit comprises second metal posts coupled between the second semiconductor die and respective overlapping parts of the second metal plane, the secondary side terminals, and the inner secondary coil portion.

In at least one example, a packaged integrated circuit is provided which comprises a package substrate including a first transformer and a second transformer, the first transformer having first primary side terminals and first secondary side terminals, the second transformer having second primary side terminals and second secondary side terminals, in which the first primary side terminals, the first secondary side terminals, the second primary side terminals, and the second secondary side terminals are on a metal layer of the package substrate. In at least one example, the packaged integrated circuit comprises a first semiconductor die coupled to the first primary side terminals and the second primary side terminals. In at least one example, the packaged integrated circuit further comprises a second semiconductor die and coupled to the first secondary side terminals and the second secondary side terminals.

In at least one example, a packaged integrated circuit is provided which comprises a package substrate including a transformer having a primary coil and a secondary coil. In at least one example, the packaged integrated circuit comprises a first semiconductor die on the package substrate and partially overlapping the primary coil, wherein the first semiconductor die includes a first metal plane which is floating. In at least one example, the packaged integrated circuit comprises a set of pillars coupled to the primary coil and the first metal plane. In at least one example, the packaged integrated circuit includes a second semiconductor die on the package substrate and partially overlapping the secondary coil, wherein the first semiconductor die and the second semiconductor die are symmetrically arranged relative to a center of the transformer.

In at least one example, a method is provided which comprises forming a package substrate including a first metal plane on a first side, a second metal plane on a second side opposing the first side, and a transformer laterally between the first and second metal planes, the transformer including a primary winding and a secondary winding, the primary winding includes outer primary coil portions having first and second primary side terminals and an inner primary coil portion, and the secondary winding includes outer secondary coil portions having first and second secondary side terminals and an inner secondary coil portion. In at least one example, the method comprises coupling a first semiconductor die on the first side of the package substrate. In at least one example, the method comprises overlapping the first semiconductor die over at least parts of the outer primary coil portions, the inner primary coil portion, and the first metal plane. In at least one example, the method comprises coupling a second semiconductor die on the second side of the package substrate. In at least one example, the method further comprises overlapping the second semiconductor die over at least parts of the outer secondary coil portions, the inner secondary coil portion, and the second metal plane. In at least one example, the method comprises coupling first metal posts between the first semiconductor die and the respective overlapping parts of the first metal plane, the primary side terminals, and the inner primary coil portion. In at least one example, the method comprises coupling second metal posts between the second semiconductor die and respective overlapping parts of the second metal plane, the secondary side terminals, and the inner secondary coil portion.

### BRIEF DESCRIPTION OF THE DRAWINGS

The examples will be understood more fully from the detailed description given below and from the accompanying drawings, which, however, should not be taken to limit the disclosure to the specific examples, but are for explanation and understanding only.

FIG. 1 is a schematic depicting an example packaged integrated circuit (IC) having an integrated isolation circuit, in accordance with at least one example.

FIG. 2 is a schematic illustrating a packaged IC having an integrated isolation circuit including inductive isolation channels coupled to the first and second semiconductor dies, in accordance with at least one example.

FIG. 3 is schematic showing an isometric view of a packaged IC having an integrated isolation circuit including an inductive channel coupled within the packaged IC, in accordance with at least one example.

FIG. 4 is a schematic showing a side view of the packaged IC of FIG. 3, in accordance with at least one example.

FIGS. 5A-B are schematics showing top views of packaged IC of FIG. 3 having a power transformer in the first and second metal layers, respectively, in accordance with some examples.

FIGS. 5C-D are schematics showing top views of the packaged IC of FIG. 3 having one or more data transformers in the first and second metal layers, respectively, in accordance with some examples.

FIG. 6 is a schematic showing a top view of a packaged IC with partially overlapping primary and secondary windings of the data transformers, in accordance with at least one example.

FIG. 7A is a schematic showing a top zoomed-in view of the packaged IC of FIG. 6 with the partially overlapping primary and secondary windings of the data transformers, in accordance with at least one example.

FIG. 7B is a schematic showing an isometric top zoomed-in view of the partially overlapping primary and secondary windings of the data transformers, in accordance with at least one example.

FIG. 7C is a schematic showing an isometric top zoomed-in view of the partially overlapping primary and secondary windings of the data transformers, in accordance with at least one example.

FIG. 8 is a schematic showing a DC-DC converter formed on two semiconductor dies coupled by a power transformer, in accordance with at least one example.

FIG. 9 is a flowchart of a method of forming the packaged IC with three transformers, in accordance with at least one example.

### DETAILED DESCRIPTION OF EXAMPLE EMBODIMENTS

Described herein is a packaged integrated circuit (IC) that comprises two semiconductor dies that are coupled to an isolation circuit (e.g., an isolation barrier) which is integrated within a package substrate. In at least one example, the package substrate includes two metal layers. The semiconductor dies include a first semiconductor die with a first power IC and a second semiconductor die with a second power IC, where the first semiconductor die is coupled to the second semiconductor die via a power transformer which is part of the isolation circuit. In at least one example, the first semiconductor die and the second semiconductor die include data circuits that are coupled via a data transformer (or a set of data transformers), which is also part of the isolation circuit. The data circuits provide bidirectional signaling, in accordance with at least one example. In at least one example, the data transformer or the set of data transformers are positioned within a footprint of the power transformers. In at least one example, semiconductor dies are flip-chip dies that allow connection with the transformer(s) below it with reduced interconnection.

In at least one example, the data circuits are used for sending and receiving signals between the first and second power semiconductor dies to realize a DC-DC converter. In at least one example, the data circuits can be used for other functions such as telemetry, data signaling, buffering of analog input signals for an analog-to-digital converter, buffering of digital input signals for a digital-to-analog converter, etc. In at least one example, the data transformer can be multiplexed between sending internal data (e.g., feedback data from the secondary side back to the primary side within the packaged IC) and external data (e.g., external to the packaged IC). In at least one example, an additional semiconductor die is positioned on the package substrate, where the additional semiconductor die receives power from the second power semiconductor die and data from the data circuit. The additional semiconductor die can be any application specific semiconductor die or a general microcontroller.

By integrating the semiconductor dies for power regulation and data transfer with the isolation circuit, which is integrated in the package substrate, overall size of the packaged IC is reduced. The flip-chip assembly for the semiconductor dies allows for tighter parameter control which reduces the size or area of the packaged IC, which can result in shorter and/or fewer interconnect routing, closer connections, smaller parasitic capacitances, resistances, and/or inductances, etc. Flip-chip dies can overlap the transformers, which can reduce parasitic capacitances, resistances, and/or inductances involved in connecting the transformers to the flip-chip dies. Routing over the package substrate (e.g., using wire bonding) can be eliminated or at least reduced as most signal and power routings can be in the package substrate. The reduced parasitic capacitances, resistances, and/or inductances involved in connecting the transformers of the isolation circuit with respect to a bonded assembly, allow tailoring of the power and data channels down to the application needs and achieve higher power transfer efficiency. Reduced parasitic capacitances, resistances, and/or inductances increase transformer coupling that also translate to higher power transfer efficiency. Other technical effects realized from reduced parasitic capacitances, resistances, and/or inductances include reduction of supply ringing which lowers reliability concerns in the semiconductor dies, and better control on routing which improves data immunity performance.

Also, in some examples, additional interconnects can be coupled between the transformer and the overlapping semiconductor dies. The semiconductor dies, as well as the package substrate, may include floating metal layers that are electrically isolated from other signal and power traces. The interconnects can be coupled to the floating metal layers in the semiconductor dies, and the floating metal layers in the semiconductor dies and in the package substrate can also be coupled. The interconnects can function as thermal bumps and provide a thermal conductive path from the transformer to the package substrate, via the floating metal layers in the semiconductor die, to facilitate heat removal from the transformer, and the heat can then be dissipated via the metal layers in the package substrate. Such arrangements can facilitate thermal management, especially in a case where the transformer is part of a power converter and conducts a large amount of current. Also, by overlapping the transformer with the semiconductor dies, the thermal bumps can be further shortened to reduce the thermal conduction distance, which can further facilitate heat removal from the transformer.

Moreover, by placing the transformers of the isolation circuit in the package substrate, which can be much thicker than the transformer windings, the vertical separation between the transformer windings and the semiconductor die can be increased, at least compared with the case where the transformer windings (or other isolation circuit) formed in the metallization layer over the semiconductor die. Such arrangements can reduce the parasitic capacitance between the transformer windings and the semiconductor die, which can provide connection to ground. The reduced parasitic capacitance can improve the quality factor (QF) of the transformer. The increased vertical separation can also reduce the eddy current in the semiconductor die caused by the magnetic field generated by the transformer, which can reduce loss and further improve power transfer efficiency. Further, as explained below, the transformer can also provide improved common mode transient immunity and improved matching for differential signals.

The flexibility in the routing capability of the package substrate also improves the connectivity and signal integrity of the serviced application specific IC. The packaged IC of some examples integrate power and bidirectional data communication with minimized crosstalk, so that they operate independently, which makes the use of the isolated co-packaged device more flexible. In at least one example, the package substrate comprising two metal layers improves efficiency for power transformers using thicker metal (e.g., copper) traces. Since the semiconductor dies are over the package substrate, the transformers in the package substrate can be distanced from the semiconductor dies, which can reduce the Eddy current loss in the semiconductor substrates induced by the transformers. Accordingly, compared with transformers that are integrated in the silicon metallization layers, transformers in the package substrate can have higher QFs. Embedding the data transformers in the substrate also allows for high frequency signal communication between data integrated circuits. Routing signal and power through a package substrate having two metal layers reduces interconnect congestion on top of the substrate, which allows for smaller packaged integrated circuit as semiconductor dies in the packaged integrated circuit are placed closer to one another.

In at least one example, the windings of the power transformer are point symmetric around, for example, a center of the packaged integrated circuit, or another location of the packaged integrated circuit. In at least one example, the windings of the data transformer are also point symmetric around the center. The point symmetry also holds for traces and placement of semiconductor dies. In some examples, the primary side terminals can receive/transmit differential signals, and the secondary side terminals can also transmit/receive differential signals. The point symmetry can improve the matching between the differential signals in the primary side terminals (and transmitted/received via the primary winding), and improve the matching between the differential signals in the secondary side terminals (and transmitted/received via the secondary winding). The improved matching can improve immunity to common mode noise, including common mode noise caused by electromagnetic interference (EMI).

The symmetry can also reduce EMI radiation from the packaged IC. Specifically, one main EMI contributor is the antenna created between primary and secondary ground planes at the printed circuit board (PCB) on which the packaged IC is mounted. Asymmetries in the transformer and in the semiconductor die inside the packaged IC can induce a current flowing through the transformer barrier capacitance and closing through the external parasitic capacitance between the PCB ground planes, which generates a voltage across the PCB ground planes. The voltages at the PCB ground planes can move with respect to each other with time, and the PCB acts as a dipole antenna radiating the electromagnetic waves caused by the time-varying voltage. The radiation can create disturbance to other devices on the PCB. The symmetry in the transformer can reduce the current flowing through the transformer barrier capacitance and reduce the voltage across the PCB ground planes, hence reducing the EMI radiation.

In the drawings, like reference numerals refer to like elements throughout, and the various features are not necessarily drawn to scale. Here, the same reference numbers or other reference designators are used in the drawings to designate the same or similar (either by function and/or structure) features.

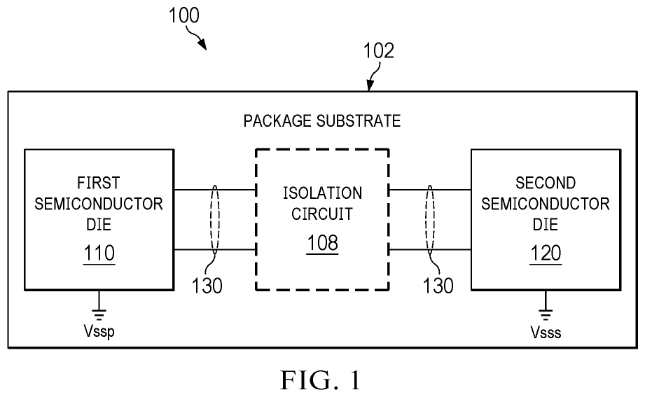

FIG. 1 is a schematic depicting a packaged IC 100 having an integrated isolation circuit, in accordance with at least one example. In at least one example, packaged IC 100 includes a package substrate 102, such as a lead frame, an integrated isolation circuit 108, a first semiconductor die 110, and a second semiconductor die 120. Semiconductor dies 110 and 120 are mounted to package substrate 102, which can support first and second semiconductor dies 110 and 120 as a circuit support structure.

In at least one example, integrated isolation circuit 108 is integrated, formed, or embedded into layers (not shown) of package substrate 102, as indicated by dashed lines. In at least one example, package substrate 102 includes contact pads (not shown) and may include metallic interconnects 130 (four shown) to allow interconnectivity between first and second semiconductor dies 110 and 120 and integrated isolation circuit 108. Each interconnect 130 may represent one or more electrical traces and/or vias.

In at least one example, integrated isolation circuit 108 (and other isolation circuit examples in accordance with this description) may provide a galvanic isolation barrier between two different power domains. In at least one example, packaged IC 100 can include a direct current (DC)-to-DC converter having a transformer as integrated isolation circuit 108. Accordingly, first semiconductor die 110 may include circuits, such as a half-bridge circuit or a full-bridge circuit and a driver circuit, for providing a voltage and a current from other circuit to a primary winding of the transformer. In at least one example, the voltage and the current are provided from a power supply for a printed circuit board (PCB) on which package substrate 102 is mounted. The PCB may be used to power a device such as a motor or a computing device. In at least one example, second semiconductor die 120 may include a bridge circuit and a driver and regulation circuit for receiving a voltage and a current from a secondary winding of the transformer and providing one or more regulated output voltages and/or currents for use by a load on the PCB. The load may be an application-specific integrated circuit (ASIC), a field-programmable gate array (FPGA), a microcontroller, a processor, etc. In at least one example, first and second semiconductor dies 110 and/or 120 may represent controller circuit, current and voltage sensors, gate drivers for insulated-gate bipolar transistors, gate drivers for field effect transistors (FETs), etc.

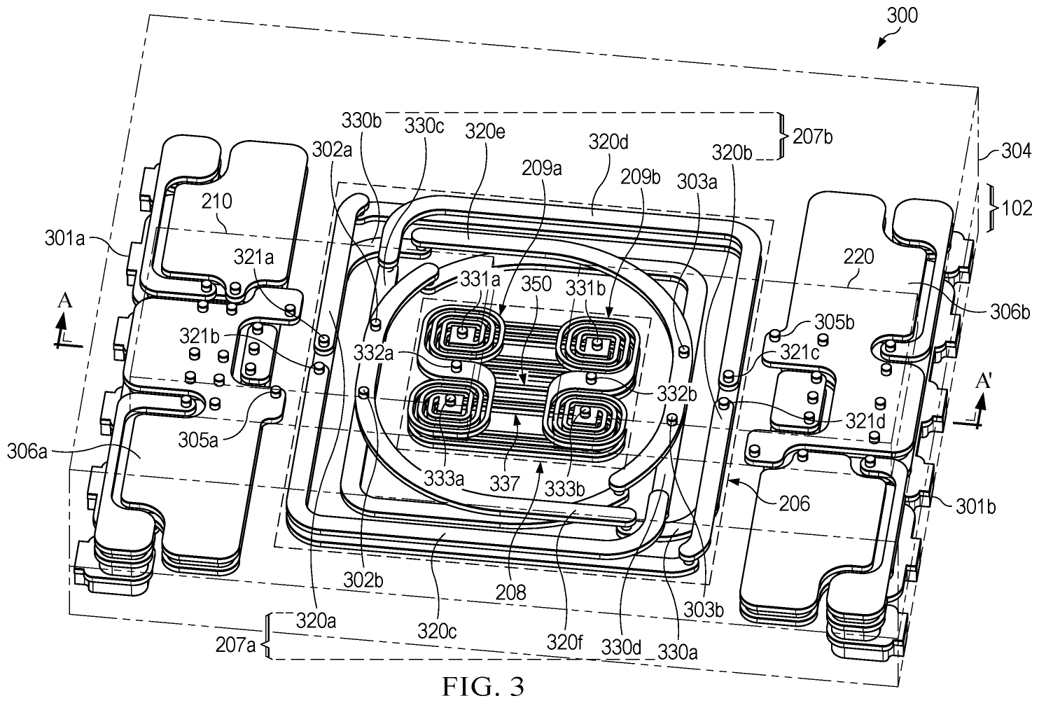

In at least one example, integrated isolation circuit 108 may include one or more isolation circuits. In at least one example, integrated isolation circuit 108 includes transformers, for instance as shown in FIGS. 3, 4, 5A, 5B, 5C, 5D, 6, 7A, 7B, and 7C.

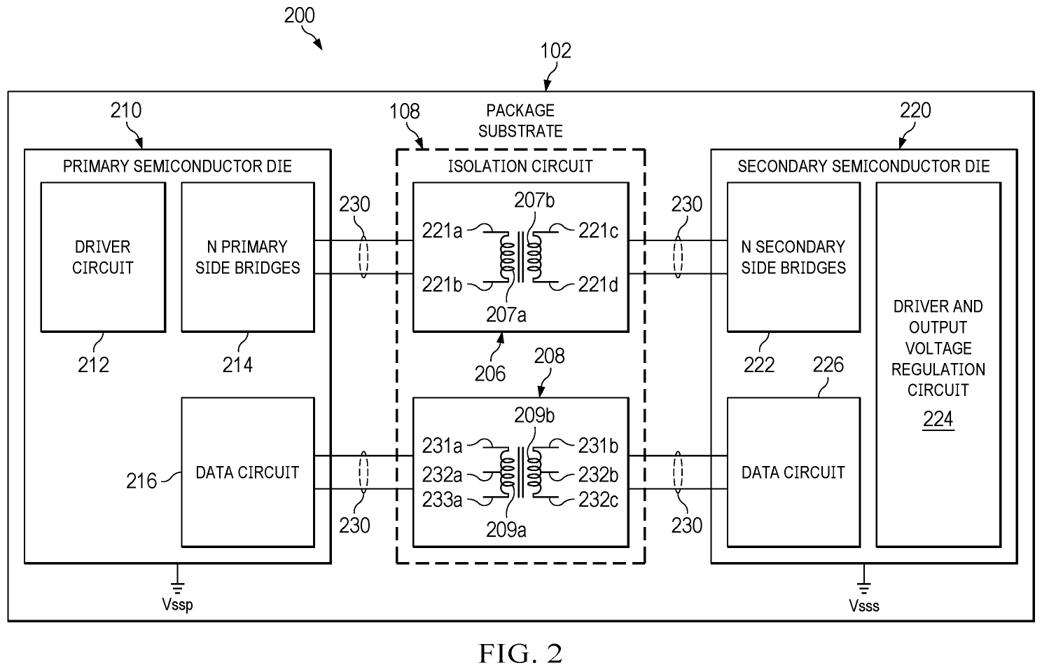

FIG. 2 is a schematic illustrating a packaged IC 200 having an integrated isolation circuit including inductive isolation channels coupled to the first and second semiconductor dies, in accordance with at least one example. In at least one example, packaged IC 200 includes a package substrate 102, a first semiconductor die 210 (e.g., a primary side circuit), and a second semiconductor die 220 (e.g., a secondary side circuit). First and second semiconductor dies 210 and 220 are mounted on package substrate 102. In at least one example, package substrate 102 includes fiberglass-based materials that use etched copper layers and drilled vias instead of electroplated layers and vias. In at least one example, integrated isolation circuit 108 is integrated into layers (not shown) of package substrate 102, as indicated by dashed lines. Moreover, package substrate 102 includes contact pads (not shown) and metallic interconnects 230 (eight shown) to allow interconnectivity between first and second semiconductor dies 210 and 220 and integrated isolation circuit 108. Each interconnect 230 may represent one or more electrical traces and/or vias.

In at least one example, integrated isolation circuit 108 includes power transformer 206 and data transformer 208. In at least one example, power transformer 206 comprises two windings/turns implemented in two metal layers of package substrate 102. Power transformer 206 includes one or more primary windings and one or more secondary windings, such as a primary winding 207a and a secondary winding 207b. In at least one example, primary winding 207a is implemented in two metal layers of package substrate 102 and secondary winding 207b is implemented in two metal layers of package substrate 102. In at least one example, data transformer 208 includes one or more primary windings and one or more secondary windings, such as a primary winding 209a and a secondary winding 209b. In at least one example, data transformer 208 includes a third winding that couples primary winding 209a and secondary winding 209b, where the third winding is in a different metal layer than primary winding 209a and secondary winding 209b.

In at least one example, first semiconductor die 210 is coupled to N primary windings of N power transformers, such as a primary winding 207a of power transformer 206, and includes a driver circuit 212, N primary side bridges 214, and a data circuit 216 (e.g., digital communicator). N can be one or more. Primary winding 207a is coupled between primary side terminals 221a and 221b. In at least one example, data circuit 216 can be on the same semiconductor die or a separate semiconductor die from driver circuit 212 and bridges 214. Any suitable circuit configuration may be used for driver circuit 212, primary side bridges 214, and data circuit 216. Each of the N primary side bridges 214 is coupled to a primary winding of a respective one of power transformers (e.g., primary winding 207a of power transformer 206) by a respective interconnect 230 of package substrate 102. For example, at least one of primary side bridges 214 is coupled to primary side terminals 221a and 221b of primary winding 207a of power transformer 206. Driver circuit 212 provides a control function to N primary side bridges 214. In turn, each of the primary side bridges 214 provides a voltage to a respective power transformer 206 using a respective one of interconnects 230. The current example includes two primary side bridges 214 and power transformer 206, as illustrated by the two interconnects 230 coupled therebetween.

In at least one example, second semiconductor die 220 includes N secondary side bridges 222 coupled to N secondary windings of N power transformers, such as a secondary winding 207b of power transformer 206, a driver and output voltage regulation circuit 224, and a data circuit 226 (e.g., a digital communicator). Data circuit 226 can be on the same semiconductor die or a separate semiconductor die from driver circuit 224 and bridges 222. Any suitable circuit configuration may be used for secondary side bridges 222, driver and output voltage regulation circuit 224, and data circuit 226. Each of N secondary side bridges 222 is coupled to a secondary winding of power transformer (e.g., secondary winding 207b of power transformer 206) by a respective interconnect 230 of package substrate 102. Secondary winding 207b is coupled between secondary side terminals 221c and 221d. At least one of secondary side bridges 222 is coupled to secondary winding 207b through secondary side terminals 221c and 221d. Driver circuit 224 provides a control function to secondary side bridges 222. In turn, each of secondary side bridges 222 receives a voltage from data transformer 208 using a respective one of interconnects 230. An output voltage regulator (VR) of circuit 224 receives and regulates the voltage from secondary side bridges 222, for instance using a feedback loop.

In at least one example, primary winding 207a of power transformer 206 is situated in two layers of package substrate 102, where half of primary winding 207a are in a first metal layer of package substrate 102 and the other half of primary winding 207a are in a second metal layer of package substrate 102, the second metal layer below the first metal layer. In at least one example, primary winding 207a is also coupled to data circuit 216 and secondary winding 207b is also coupled to data circuit 226. Like primary winding 207a, half of secondary winding 207b are in the first metal layer of package substrate 102 and the other half of secondary winding 207b are in the second metal layer of package substrate 102. In at least one example, first and second semiconductor dies 210 and 220 overlap portions of power transformer 206 and data transformer 208 such that the arrangement of first and second semiconductor dies 210 and 220, power transformer 206, and data transformer 208 are point symmetrical around, for example, the center of packaged IC 200 or other locations of packaged IC 200. In at least one example, the point of symmetry is the center power of transformer 206.

In at least one example, data circuit 216 provides a first data signal to primary winding 209a of data transformer 208 via interconnects 230, and data circuit 226 receives the first data signal from secondary winding 209b via interconnects 230. Data circuit 226 can also provide a second data signal to secondary winding 209b of data transformer 208 via interconnects 230, and data circuit 216 can receive the second data signal from primary winding 209a and interconnects 230. In at least one example, primary winding 209a is coupled between primary side terminals 231a and 233a and includes a center tap 232a, where primary side terminals 231a and 233a are coupled to a differential transmitter or receiver of data circuit 216 via interconnects 230, and where center tap 232a is coupled to local ground Vssp. In at least one example, secondary winding 209b is coupled between secondary side terminals 231b and 233b and includes a center tap 232b, where secondary side terminals 231b and 233b are coupled to a differential transmitter or receiver of data circuit 226 via interconnects 230, and where center tap 232b is coupled to local ground Vsss. In at least one example, the first data signal may originate from an external data source, and the second data signal may target an external data sink. Accordingly, in such examples, data transformer 208 can be used for bi-directional or uni-directional data transfer unrelated to the power converter formed by driver circuitry 212, N primary side bridges 214, N secondary side bridges 222, and driver and output VR circuitry 224. One such use of data transformer 208 for both data and power circuits is discussed by U.S. patent application Ser. No. 17/363,470, filed Jun. 30, 2021, titled “Data Transfer Through An Isolated Power Converter,” U.S. patent application Ser. No. 17/943,020 filed Sep. 12, 2022, titled “Power Supply Conversion Circuit and Power Supply Conversion Method,” which is incorporated by reference in its entirety.

In at least one example, the number of primary windings of data transformer 208 is equal to the number of secondary windings of data transformer 208. In at least one example, the number of primary windings of data transformer 208 is different from the number of secondary windings of data transformer 208. In at least one example, the size of data transformer 208 is smaller than the size of power transformer 206. In at least one example, data transformer 208 is surrounded by or resides within a footprint of power transformer 206. In at least one example, data transformer 208 can be used for bi-directional or uni-directional data transfer unrelated to the power converter formed by driver circuit 212, N primary side bridges 214, N secondary side bridges 222, and driver and output VR circuit 224. In at least one example, data transformer 208 is used for bi-directional or uni-directional data transfer directly related to controlling of the power converter formed by driver circuit 212, N primary side bridges 214, N secondary side bridges 222, and driver and output VR circuit 224. Data transformer 208 may include two or more transformers, one for each data or signal line.

In at least one example, data transformer 208 and interconnects 230 allow bidirectional data communication, for example controller area network (CAN) or CAN flexible data rate (FD) protocol communication or RS-485 protocol communication. Namely, data circuit 216 may provide a data signal to primary winding 209a of data transformer 208 and receive a data signal from secondary winding 209b of data transformer 208 over respective interconnects 230.

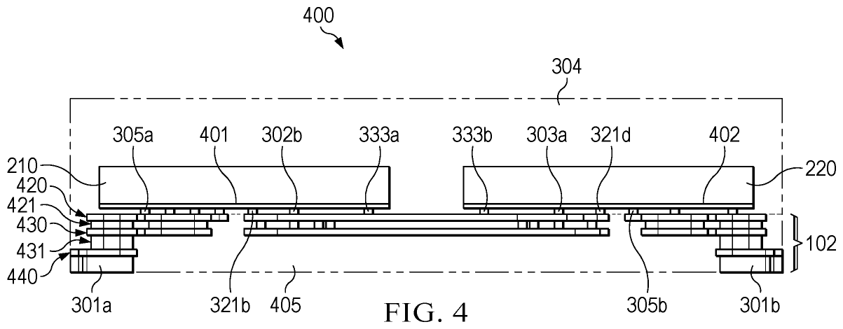

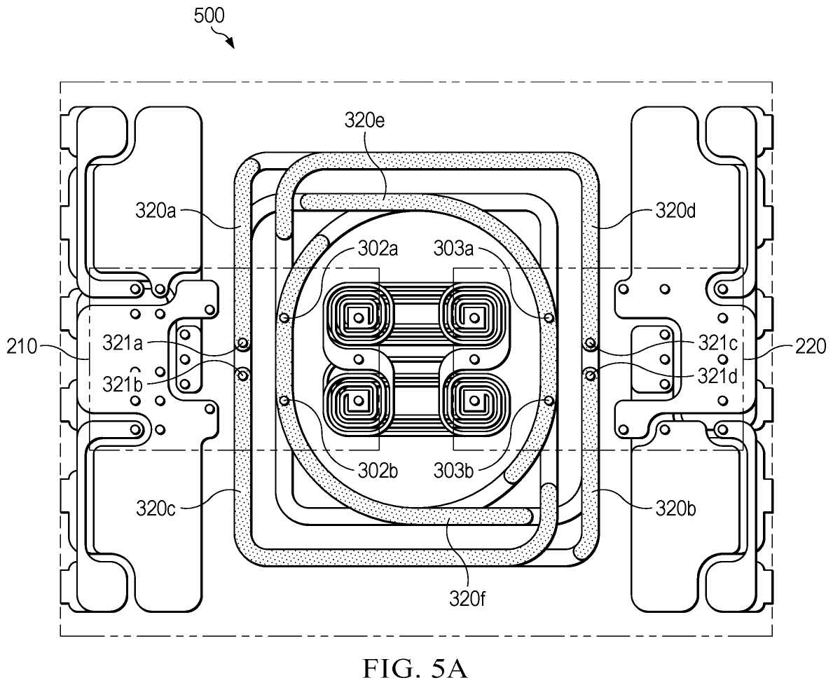

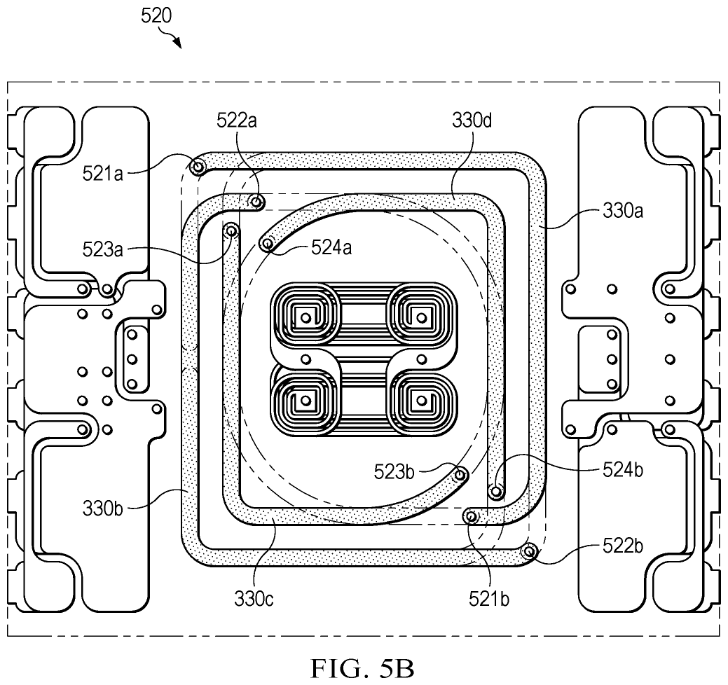

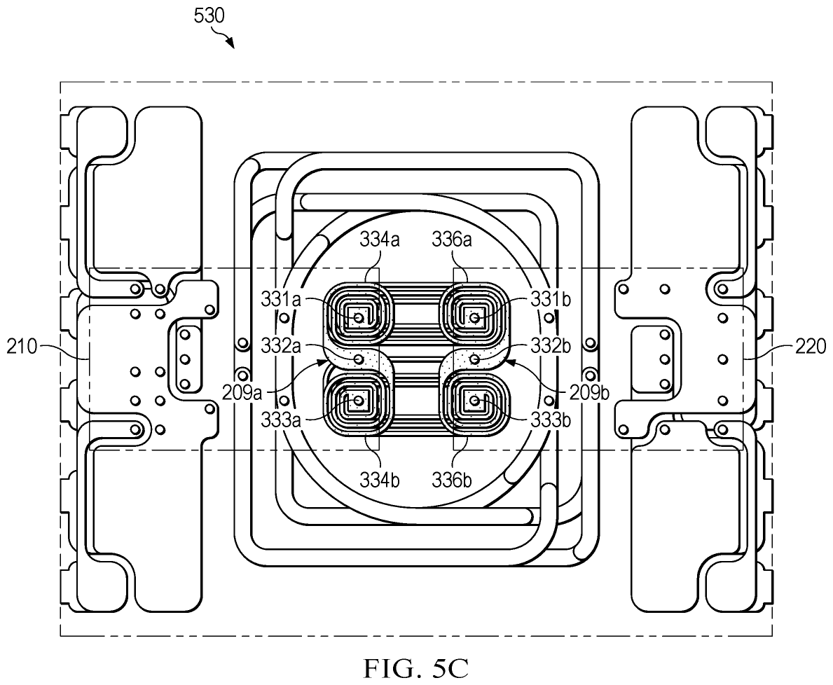

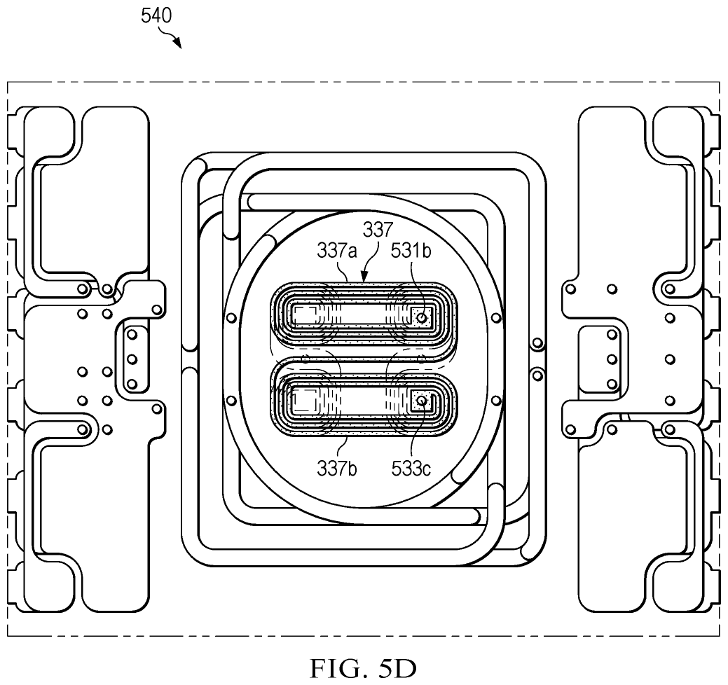

FIG. 3 is schematic showing an isometric view of a packaged IC 300 having an integrated isolation circuit including an inductive channel coupled within packaged IC 300, in accordance with at least one example. FIG. 4 is a schematic showing a side view of packaged IC 300 (herein packed IC 400) shown in FIG. 3, in accordance with at least one example. FIGS. 5A-B are schematics showing top views of packaged IC 300 (herein packaged IC 500 and packaged IC 520) having a power transformer in the first and second metal layers, respectively, in accordance with some examples. FIGS. 5C-D are schematics showing top views of packaged IC 300 (herein packaged IC 530 and packaged IC 540) having one or more data transformers in the first and second metal layers, respectively, in accordance with some examples.

In at least one example, package substrate 102 includes pin interfaces 301a on a first side of package substrate 102, and pin interfaces 301b on a second side of package substrate 102, the second side opposing the first side. In at least one example, package substrate 102 includes a first metal plane 306a on the first side, and a second metal plane 306b on the second side. In some examples, metal planes 306a and 306b can be floating metal layers isolated from other metal layers/traces for transmission of power and/data and can be used for heat dissipation. In at least one example, metal posts or pillars 305a couple first semiconductor die 210 with power and signal planes on the first side, while metal posts or pillars 305b couple second semiconductor die 220 with power and signal planes on the second side.

In at least one example, power transformer 206 is laterally positioned between first plane 306a and second metal plane 306b. Power transformer 206 includes primary winding 207a coupled between metal posts/pillars 321a and 321b, and secondary winding 207b coupled between metal posts/pillars 321c and 321d.

In at least one example, primary winding 207a includes a first outer primary coil portion 320a, a second outer primary coil portion 320c, an inner primary coil portion 320f, a first primary lower coil portion 330a, and a second primary lower coil portion 330d. As to be described below, first outer primary coil portion 320a, second outer primary coil portion 320c, and inner secondary coil portion 320f can be in a first metal layer of the package substrate 102, and first primary lower coil portion 330a and second primary lower coil portion 330d can be in a second metal layer of the package substrate 102 below the first metal layer. In at least one example, primary side terminals 221a and 221b are coupled to metal posts or pillars 321a and 321b to receive/transmit a voltage and a current from/to the first semiconductor die 210. In at least one example, the inner primary coil portion 320f is coupled to metal posts or pillars 302a and 302b, which can be coupled to floating metal layers on a semiconductor substrate of the first semiconductor die 210 as thermal bumps to facilitate conduction of heat away from primary winding 207a to metal plane 306a.

In at least one example, the secondary winding 207b is coupled between secondary side terminals 221c and 221d. In at least one example, secondary winding 207b includes a first outer secondary coil portion 320b, a second outer secondary coil portion 320d, an inner secondary coil portion 320e, a first secondary lower coil portion 330b, and a second secondary lower coil portion 330c. As to be described below, first outer secondary coil portion 320b, second outer secondary coil portion 320d, and inner secondary coil portion 320e can be in the first metal layer of the package substrate 102, and first secondary lower coil portion 330b and second secondary lower coil portion 330c can be in the second metal layer below the first metal layer. In at least one example, secondary side terminals 221c and 221d which are coupled to metal posts or pillars 321c and 321d, respectively, to receive/transmit a voltage and a current from/to the second semiconductor die 220. In at least one example, inner secondary coil portion 320e is coupled to metal posts or pillars 303a and 303b, which can be coupled to floating metal layers on a semiconductor substrate of the second semiconductor die 220 as thermal bumps to facilitate conduction of heat away from secondary winding 207b to metal plane 306b.

In at least one example, first semiconductor die 210 is on the first side of package substrate 102 and overlaps at least parts of the outer primary coil portions (e.g., first outer primary coil portion 320a and second outer primary coil portion 320c), inner primary coil portion 320f, and first metal plane 306a. In at least one example, second semiconductor die 220 is on the second side of package substrate 102 and overlaps at least parts of the outer secondary coil portions (e.g., first outer secondary coil portion 320b and second outer secondary coil portion 320d), inner secondary coil portion 320e, and second metal plane 306b.

As described above, packaged IC 300 includes first metal posts or pillars, such as 302a, 302b, 321a, and 321b, coupled between first semiconductor die 210 and the respective overlapping parts of first metal plane 306a, primary side terminals 221a and 221b, and inner primary coil portion 320f. Metal posts/pillars 302a and 302b can be a first subset of the first metal posts/pillars, and metal posts/pillars 321a/321b can be a second subset of the first metal posts/pillars. Also, packaged IC 300 includes second metal posts or pillars, such as 303a, 303b, 321c, and 321d, coupled between second semiconductor die 220 and respective overlapping parts of second metal plane 306b, secondary side terminals 221c and 221d, and inner secondary coil portion 320e. Metal posts/pillars 303a and 303b can be a first subset of the second metal posts/pillars, and metal posts or pillars 321c/321d can be a second subset of the second metal posts/pillars, where metal posts or pillars 321c and 321d are coupled to secondary side terminals 221c and 221d, respectively.

In at least one example, first semiconductor die 210 includes a first circuit (e.g., primary side bridge 214) coupled to primary side terminals 221a and 221b which are coupled to metal posts or pillars 321a and 321b. First outer primary coil portion 320a is coupled to primary side terminal 221a which is coupled to metal post or pillar 321a, while second outer primary coil portion 320c is coupled to primary side terminal 221b which is coupled to metal post or pillar 321b. The first circuit can be electrically isolated from the floating metal layers of the first semiconductor die 210, which can be part of a third circuit of the first semiconductor die 210.

In at least one example, second semiconductor die 220 includes a second circuit (e.g., secondary side bridge 222) coupled to secondary side terminals 221c and 221d which are coupled to metal posts or pillars 321c and 321d, respectively. First outer secondary coil portion 320b is coupled to secondary side terminal 221d via metal post or pillar 321d, and second outer secondary coil portion 320d is coupled to secondary side terminal 221c via metal post or pillar 321c. The second circuit can be electrically isolated from the floating metal layers of the second semiconductor die 220, which can be part of a fourth circuit of the second semiconductor die 220.

As described above, the third circuit of first semiconductor die 210 may include a first floating metal layer on or in a first semiconductor substrate of first semiconductor die 210. In at least one example, the fourth circuit of second semiconductor die 220 may include a second floating metal layer on or in a second semiconductor substrate of second semiconductor die 220. The first and second floating metal layers are not connected to ground, power supply, or a bias voltage. The first and second floating metal layers are coupled to pin interfaces 301a and 301b, and radiate heat away from power transformer 206 and/or data transformer 208 out of packaged IC 300. This allows for thermal management of packaged IC 300, in accordance with at least one example.

Referring to FIG. 4, in at least one example, first semiconductor die 210 and second semiconductor die 220 include first and second metal layers 401 and 402, respectively. In at least one example, first and second metal layers 401 and 402 couple to thermal bumps (e.g., metal posts/pillars 302a, 302b, 303a, 303b) of primary and/or secondary windings 207a/207b of transformer 206 to transfer heat from integrated isolation circuit 108 to first and second metal layers 401 and 402. In at least one example, first and second metal layers 401 and 402 include floating metal layers in that they are not connected to ground, supply, or any other voltage source. Heat from integrated isolation circuit 108 radiates through metal posts/pillars 302a/302b connected to the inner primary coil portion 320f, and through metal posts/pillars 303a/303b connected to inner secondary coil portion 320e.

In at least one example, packaged IC 400 includes a mold compound 304 that encapsulates first and second semiconductor dies 210 and 220. In at least one example, mold compound 304 may have any suitable form such as a bulk mold compound, a sheet mold compound, an insulation build-up film, etc. In at least one example, packaged IC 400, including package substrate 102 and first and second semiconductor dies 210 and 220, is or forms a flat no-leads package, in particular a dual-flat no-leads (DFN) package. In at least one example, contact pads area used to mount packaged IC 400 to an external package substrate are arranged such that packaged IC 400 forms a quad-flat no-leads (QFN) package. In at least one example, package substrate 102 is composed of Ajinomoto build-up film (ABF) 405 (bottom dielectric which is below substrates of first and second semiconductor dies 210 and 220).

In at least one example, the material for package substrate 102 has a thickness in the z-direction and is a type that provides a galvanic isolation barrier that can withstand 5 kilovolts (kV) root mean square (RMS) for 60 seconds in one example and 2.5 kVRMS for 60 seconds in another example. However, different isolation ratings may be achievable based at least in part on the type and thickness of the material for package substrate 102.

In at least one example, using a mold compound, such as a compression molding film, as the material for package substrate 102, instead of a laminate, allows for a smaller critical separation between the primary and secondary windings of transformers 206 and 208 while maintaining the same voltage insulation and allows for improved thermal performance of integrated isolation circuit 108. Also, making package substrate 102 using routable lead frame technology allows for thicker copper traces (e.g., 30-35 micrometers or thicker, for instance 1%, 5%, or 10% thicker) and smaller metal width and spacing (e.g., 30×30 micrometers² or less, for instance 1%, 5%, or 10% less). This may lead to an improved efficiency of power transformer 206 and data transformer 208 by allowing an increased quality factor. Integrating power and data transformers 206 and 208 into package substrate 102 allows for smaller packaged IC sizes (e.g., 5.0×3.0×0.8 millimeters³ or less, for instance 1%, 5%, or 10% less).

As used herein, critical separation may refer to one or more minimum distances taken between first and second circuit elements (e.g., primary and secondary windings) of an isolation circuit that allows a given isolation rating to be achieved without a voltage breakdown of the isolation material between the first and second circuit elements. Accordingly, by using different types of isolation materials for package substrate 102, e.g., different types of mold compounds individually or in combination, the critical separation between primary and secondary windings can be adjusted, for instance to meet desired creepage and clearance for packaged IC 300 and to achieve lower creepage and clearance than achievable using laminate as isolation material.

In at least one example, package substrate 102 includes a first metal layer 420, a first via 421, a second metal layer 430, a second via 431, a third metal layer 40, and pin interfaces 301a and 301b for the first side and the second side of packaged IC 400. In at least one example, package substrate 102 is a multi-layer structure made using routable lead frame (RLF) technology. A metal layer, as used herein, is a layer of metal within which is formed metallic elements of a package substrate such as contact pads, vias, electrical traces, a thermal/ground pad, and circuit elements of an isolation circuit. Metal layers are positioned in substantially parallel planes to one another and are substantially planar within allowable tolerances as defined by the technology used to make the package substrate. Any suitable metal may be used to form the metal layers, such as copper, aluminum, and gold.

In at least one example, package substrate 102 includes multiple metal layers, with first metal layer 420 and second metal layer 430 used for implementing transformers 206 and 208. In one such case, third metal layer 440 may be used for routing signals from first semiconductor die 210 and second semiconductor die 330 out to a PCB via pin interfaces 301a and 301b, respectively. Here, first via 421 is between first metal layer 420 and second metal layer 430 while second via 431 is between second metal layer 430 and third metal layer 440. In at least one example, third metal layer 440 may be absent and via 431 may directly connect to pin interfaces 301a and 301b. In at least one example, the pillars and metal posts connect terminals of transformers 206 and/or 208 with first and second semiconductor dies 210 and 220.

In at least one example, first and second semiconductor dies 210 and 220 are mounted on a first surface (e.g., top surface) of package substrate 102. Package substrate 102 further includes first and second metal pads on a second surface of package substrate 102 opposing the first surface, where the first and second metal pads are connected to pin interfaces 301a and 301b, respectively. First semiconductor die 210 is coupled to at least some of the first metal pads, and second semiconductor die 220 is coupled to at least some of the second metal pads via first metal layer 420, first via 421, second metal layer 430, second via 431, third metal layer 440, and pin interfaces 301a and 301b. The first and second metal pads allow first semiconductor die 210 and second semiconductor die 220 to communicate with one or more devices outside of package substrate 102. In at least one example, the first metal pads are on the first side of package substrate 102 while the second metal pads are on the second side of package substrate 102.

Referring to FIG. 3, in at least one example, first outer primary coil portion 320a, second outer primary coil portion 320c, inner primary coil portion 320f, first outer secondary coil portion 320b, second outer secondary coil portion 320d, and inner secondary coil portion 320e are upper coil portions in the first metal layer (e.g., first metal layer 420). In at least one example, the second metal layer (e.g., second metal layer 430) includes first primary lower coil portion 330a coupled between first outer primary coil portion 320a and inner primary coil portion 320f. In at least one example, the second metal layer includes second primary lower coil portion 330d coupled between inner primary coil portion 320f and second outer primary coil portion 320c. In at least one example, the second metal layer includes first secondary lower coil portion 330b coupled between first outer secondary coil portion 320b and inner secondary coil portion 320e. In at least one example, the second metal layer includes second secondary lower coil portion 330c coupled between the inner secondary coil portion 320e and second outer secondary coil portion 320d.

In at least one example, first primary lower coil portion 330a overlaps the first and second secondary terminals and at least parts of first outer secondary coil portion 320b and second outer secondary coil portion 320d. In at least one example, second primary lower coil portion 330d overlaps at least a part of the inner primary coil portion 320f. In at least one example, first secondary lower coil portion 330b overlaps the first and second primary terminals and at least parts of the first outer primary coil portion 320a and second outer primary coil portion 320c. In at least one example, second secondary lower coil portion 330c overlaps at least a part of inner secondary coil portion 320e.

In at least one example, first outer primary coil portion 320a, second outer primary coil portion 320c, and inner primary coil portion 320f are at point symmetry 350 with respect to, respectively, first outer secondary coil portion 320b, second outer secondary coil portion 320d, and the inner secondary coil portion 320e. In at least one example, first primary lower coil portion 330a and second primary lower coil portion 330d are at point symmetry 350 with respect to, respectively, first secondary lower coil portion 330b and second secondary lower coil portion 330c.

In at least one example, first outer primary coil portion 320a couples with first primary lower coil portion 330a through via 521a (e.g., first via 421) at a first end of first primary lower coil portion 330a. In at least one example, inner primary coil portion 320f couples with first primary lower coil portion 330a through via 521b (e.g., first via 421) at a second end of first primary lower coil portion 330a. In at least one example, first secondary lower coil portion 330b couples to inner secondary coil portion 320e through via 522a (e.g., first via 421) at a first end of first secondary lower coil portion 330b. In at least one example, first secondary lower coil portion 330b couples to first outer secondary coil portion 320b through via 522b (e.g., first via 421) at a second end of first secondary lower coil portion 330b. In at least one example, second secondary lower coil portion 330c couples to second outer secondary coil portion 320d through via 523a (e.g., first via 421) at a first end of second secondary lower coil portion 330c. In at least one example, second secondary lower coil portion 330c couples to inner secondary coil portion 320e through via 523b (e.g., first via 421) at a second end of second secondary lower coil portion 330c. In at least one example, second primary lower coil portion 330d couples to inner primary coil portion 320f through via 524a (e.g., first via 421) at a first end of second primary lower coil portion 330d. In at least one example, second primary lower coil portion 330d couples to second outer primary coil portion 320c through via 524b at a second end of second primary lower coil portion 330d.

In at least one example, packaged IC 300 includes second transformer 208 (e.g., a data transformer) which is laterally positioned between first plane 306a and second metal plane 306b. In at least one example, second transformer 208 is surrounded by or otherwise within a footprint of the windings of first transformer 206, first semiconductor die 210 coupled to a primary side of second transformer 208, and second semiconductor die 220 coupled to a secondary side of second transformer 208. In at least one example, second transformer 208 includes a second primary winding 209a and a second secondary winding 209b. In at least one example, second primary winding 209a includes a first coil portion 334a and a second coil portion 334b coupled to a first center tap 332a. First coil portion 334a has an end that couples to a first post 331a (e.g., primary side terminal 231a), which couples to first semiconductor die 210. Second coil portion 334b has an end that couples to a third post 333a (e.g., primary side terminal 233a) which couples to second semiconductor die 220. In at least one example, second secondary winding 209b includes a third coil portion 336a and a fourth coil portion 336b coupled to a second center tap 332b (e.g., second center tap 232b). In at least one example, first center tap 332a and second center tap 332b couple to respective ground nodes. Third coil portion 336a has an end that couples to first post 331b (e.g., secondary side terminal 231b), which couples to second semiconductor die 220. Fourth coil portion 336b has an end that couples to third post 333b (e.g., secondary side terminal 233b), which couples to second semiconductor die 220. In at least one example, first post 331a and third post 333a couple to outputs of a differential transmitter or inputs of a differential receiver in first semiconductor die 210. In at least one example, first post 331b and third post 333b couple to outputs of a differential transmitter or inputs of a differential receiver in second semiconductor die 220.

In at least one example, second transformer 208 includes a third winding 337 in the second metal layer of package substrate 102. In at least one example, second primary winding 209a and second secondary winding 209b are in first metal layer 420, and third winding 337 is in second metal layer 430. In at least one example, each of second primary winding 209a, second secondary winding 209b, and third winding 337 includes a respective figure-of-8 winding or coil.

In at least one example, the first and second center taps 332a and 332b are within a footprint of (or surrounded by) second transformer 208 (e.g., a footprint of the windings of second transformer 208). In at least one example, third winding 337 includes a fifth coil portion 337a and a sixth coil portion 337b, where the first and third coil portions 334a and 336a overlap at least part of fifth coil portion 337a, and where the second and fourth coil portions 334b and 336b overlap at least part of sixth coil portion 337a. In at least one example, fifth coil portion 337a couples to third coil portion 336a through first via 531b. In at least one example, sixth coil portion 337b couples to fourth coil portion 336b through second via 533c.

In at least one example, second primary winding 209a can have more windings or turns than the number of windings or turns of third winding 337. In at least one example, second secondary winding 209b can have more windings or turns than the number of windings or turns of third winding 337. In at least one example, second primary winding 209a and second secondary winding 209b have the same number of windings or turns. In at least one example, second primary winding 209a and second secondary winding 209b have different number of windings or turns. In at least one example, second primary winding 209a, second secondary winding 209b, and third winding 337 have figure-of-8 configurations fabricated inside power transformer 206.

In at least one example, second primary winding 209a and second secondary winding 209b are point symmetrical around point symmetry 350. In at least one example, third winding 337 is also point symmetrical around point symmetry 350. As discussed herein the windings (various inner and outer coil portions) of power transformer 206 are point symmetric around point symmetry 350. The point symmetry around point symmetry 350 also holds for traces and placement of first and second semiconductor dies 210 and 220, which reduces electromagnetic interference (EMI) footprint of packaged IC 300.

In at least one example, third winding 337 is removed and data from second secondary winding 209b inductively couples to second primary winding 209a, and vice versa. In at least one example, third winding 337 is fabricated in the second metal layer below second primary winding 209a and second secondary winding 209b, and can have portions extending in parallel with secondary winding 209b, to increase the effective inductive coupling between second primary winding 209a and second secondary winding 209b.

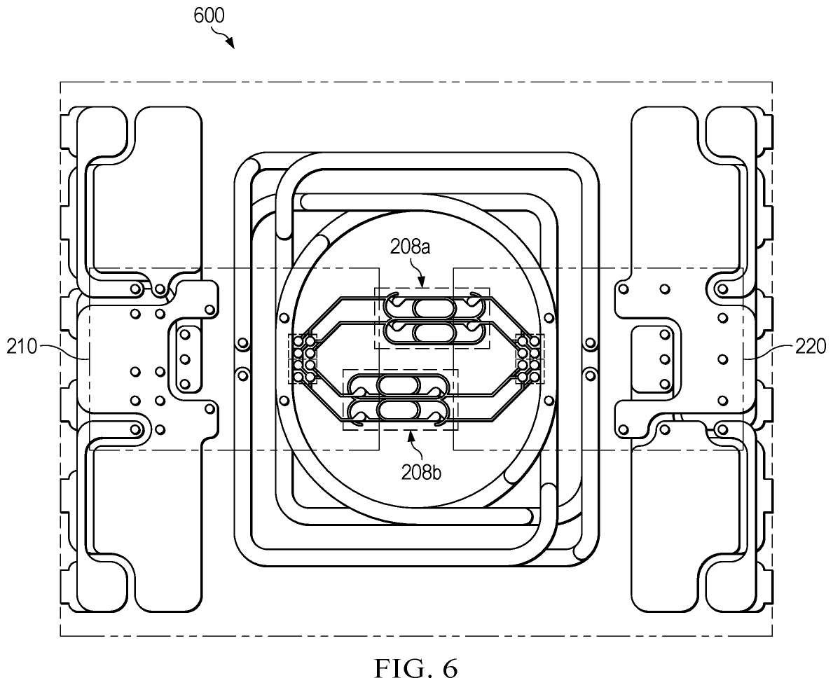

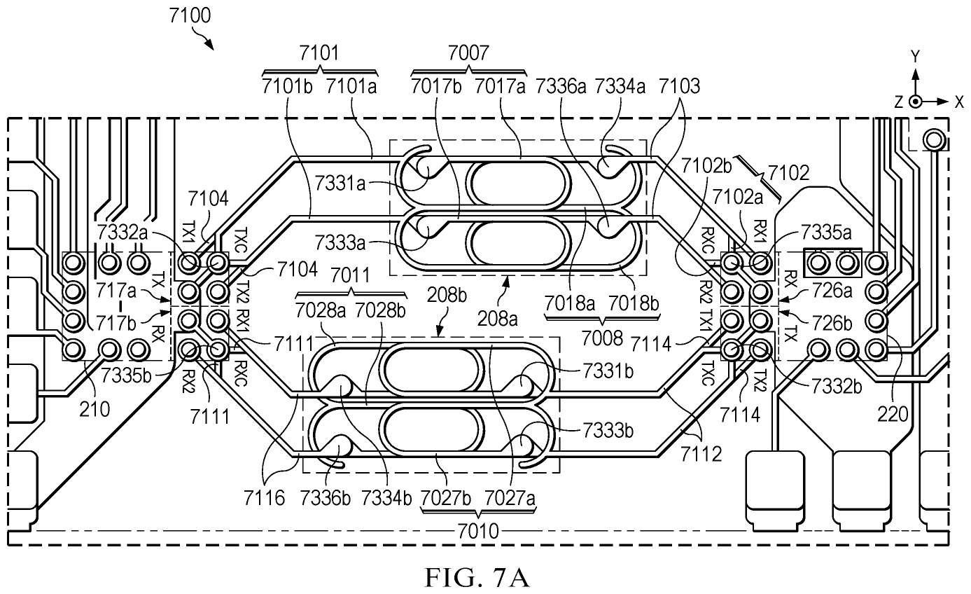

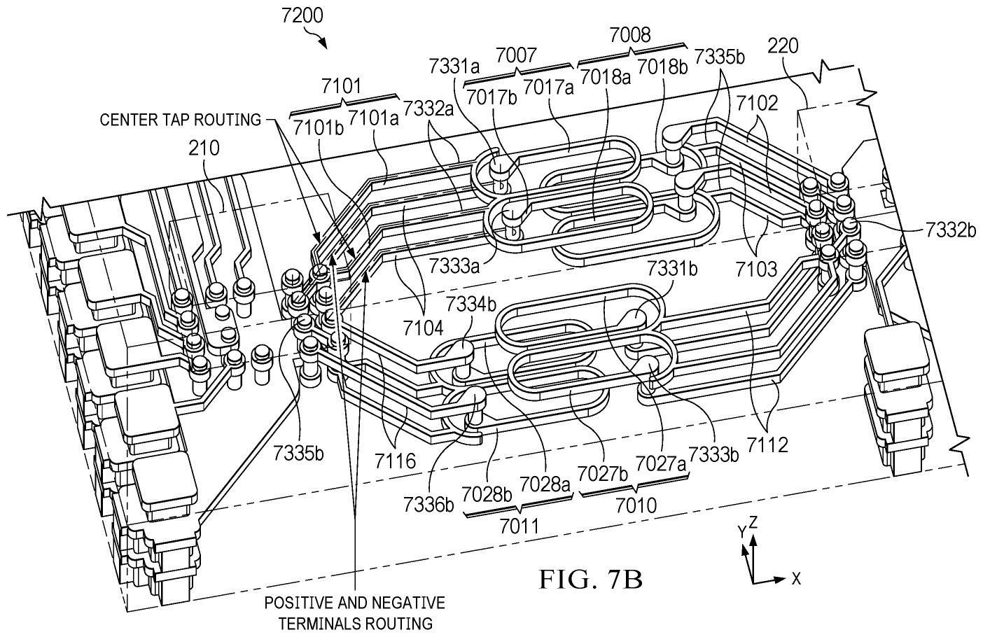

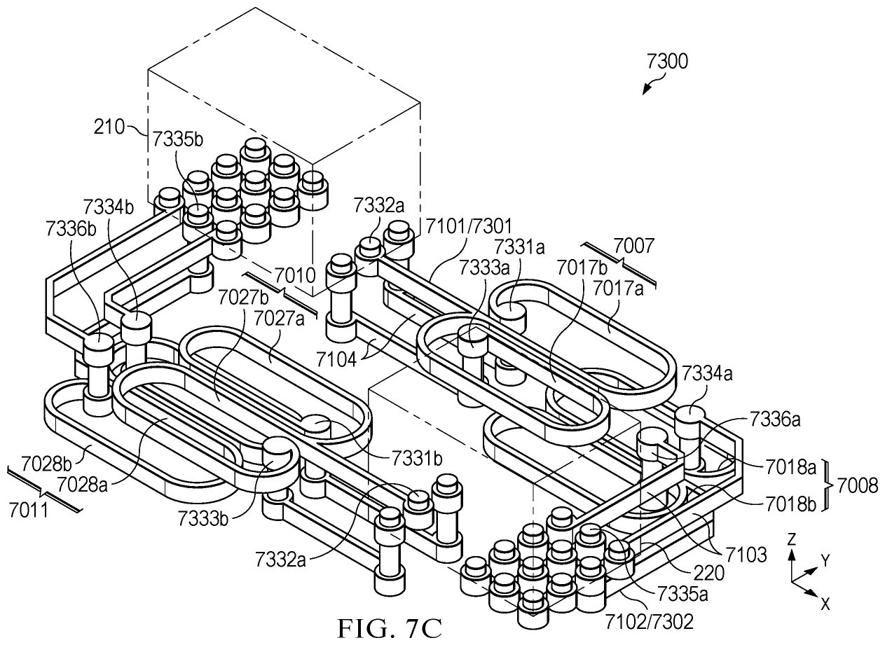

FIG. 6 is a schematic showing a top view of a packaged IC 600 with partially overlapping primary and secondary windings of the data transformers, in accordance with at least one example. FIG. 7A is a schematic showing a top zoomed-in view of packaged IC 600 of FIG. 6 (herein packaged IC portion 7100) with the partially overlapping primary and secondary windings of the data transformers, in accordance with at least one example. FIG. 7B is a schematic showing an isometric top zoomed-in view of packaged IC 600 (herein packaged IC portion 7200) the partially overlapping primary and secondary windings of the data transformers, in accordance with at least one example. FIG. 7C is a schematic showing an isometric top zoomed-in view of a data transformer of packaged IC 7300 having the partially overlapping primary and secondary windings of the data transformers, in accordance with at least one example.

Packaged IC 600 is similar in feature and function to packaged IC 300. Here, power transformer 206 remains unchanged and data transformer 208 (also referred to as the second transformer) confirmation is modified. In at least one example, second transformer 208 is split into third transformer 208a and fourth transformer 208b. In at least one example, third transformer 208a and fourth transformer 208b have different winding patterns, connection of taps, and overlapping ratio compared to secondary primary winding 209a, second secondary winding 209b, and third winding 337. Interconnects from third transformer 208a and fourth transformer 208b are coupled to transmitters and receivers of first semiconductor die 210 and second semiconductor die 220, respectively.

In at least one example, third transformer 208a includes a second primary winding 7007 and a second secondary winding 7008, which partially overlaps with each other. In at least one example, fourth transformer 208b includes a third primary winding 7010 and a third secondary winding 7011, which also partially overlap with each other. In at least one example, third and fourth transformers 208a and 208b are within the footprint of transformer 206. In at least one example, third and fourth transformers 208a and 208b are symmetrically positioned around point symmetry 350.

As described herein, winding pattern and connection of taps of third and fourth transformers 208a and 208b can improve symmetry in the connection taps. By achieving more symmetry in routing of connection taps, common mode rejection improves.

In at least one example, second primary winding 7007 is in the first metal layer (e.g., first metal layer 420 of package substrate 102) and second secondary winding 7008 is on a layer below the first metal layer. In at least one example, each of second primary winding 7007 and second secondary winding 7008 has two windings in a figure-of-8 configuration. The windings can have oval shapes (as shown in FIGS. 7A-C), or other winding shapes such as circular shapes, rectangular shapes, square shapes, etc.

In at least one example, second primary winding 7007 has a first primary side terminal 7331a, a center tap 7332a, and a second primary side terminal 7333a. In at least one example, first primary side terminal 7331a and second primary side terminal 7333a couple to outputs of a differential transmitter 717a while center tap 7332a is coupled to a ground. In FIGS. 7A-C, the center taps of transformers 208a and 208b are positioned away from the footprints of transformers 208a and 208b. For example, referring to FIG. 7A, center tap 7332a is positioned outside the footprint of transformer 208a and are coupled to second primary winding 7007 by a center tap metal interconnect 7101 that extends laterally between transformer 208a and center tap 7332a. In at least one example, the center tap metal interconnect can have matched/balanced branch portions 7101a and 7101b shown in FIGS. 7A and 7B or a straight portion of metal interconnect 7301 of FIG. 7C. In at least one example, two coil portions 7017a and 7017b extend from the branch/straight portions forming second primary winding 7007, where coil portion 7017a terminates at first primary side terminal 7331a and coil portion 7017b terminates at second primary side terminal 7333a. First primary side terminal 7331a and second primary side terminal 7333a are coupled to transmitter (TX) 717a of data circuit 216 via a pair of metal interconnects 7104, which are formed in the second metal layer 430 and under the center tap metal interconnect 7101. Symmetry/matching can be achieved by, for example, having the pair of metal interconnects 7104 overlapping with the branch portions 7101a and 7101b of the center tap metal interconnect 7101, as shown in FIG. 7A, or having the pair of metal interconnects 7104 being equal distance from the straight portion of metal interconnect 7301. In both cases, the pair of metal interconnects 7104 can have matched capacitive loading, which can improve symmetry and matching between the differential signals on metal interconnects 7104.

In at least one example, center tap 7332a is formed under data circuit 216 and coupled to data circuit 216 through a metal pillar or post (e.g., copper pillar) while first primary terminal 7331a and second primary terminal 7333a are away from data circuit 216 because second primary winding 7007 is not overlapping data circuit 216.

In at least one example, second secondary winding 7008 has similar or exact topology as second primary winding 7007 with a portion (e.g., half) of it overlapping second secondary winding 7008. In at least one example, center tap 7335a is positioned outside the footprint of transformer 208a and is coupled to second secondary winding 7008 by a center tap metal interconnect 7102 that extends laterally between transformer 208a and center tap 7335a. In at least one example, the center tap metal interconnect can have balanced/matched branch portions 7102a and 7102b shown in FIGS. 7A and 7B or a straight portion of metal interconnect 7102/7302 of FIG. 7C. Two coil portions 7018a and 7018b extend from the branch/straight portions forming second secondary winding 7008, where coil portion 7018a terminates at first secondary side terminal 7334a and coil portion 7018b terminates at second primary side terminal 7336a. First secondary side terminal 7334a and second secondary side terminal 7336a are coupled to RX 726a of data circuit 226 via a pair of metal interconnects 7103, which are formed in the second metal layer and under the center tap metal interconnect 7102. In at least one example, center tap 7335a is coupled to another ground node. Symmetry/matching can be achieved by, for example, having the pair of metal interconnects 7103 overlapping with the branch portions 7102a and 7102b of the center tap metal interconnect 7102, as shown in FIG. 7A, or having the pair of metal interconnects 7103 being equal distance from the straight portion of metal interconnect 7102/7302.

In at least one example, transformer 208b has similar or exact topology as transformer 208a. For example, center tap 7332b is positioned outside the footprint of transformer 208b and is coupled to third primary winding 7010 by a center tap metal interconnect 7112 that extends laterally between transformer 208b and center tap 7332b. Third primary winding 7010 includes coil portions 7027a and 7027b that terminate at, respectively, first primary side terminals 7331b and second primary side terminals 7333b. A pair of metal interconnects 7114 couples between data circuit 226 and first primary side terminals 7331b and second primary side terminals 7333b. Symmetry/matching can be achieved by having the pair of metal interconnects 7114 overlapping with the branch portions of metal interconnect 7112 or being equal distance from the straight portion of metal interconnect 7112. In at least one example, ranch portions of metal interconnect 7112 coupled to RX 726b of data circuit 226.

Also, center tap 7335b is also positioned outside the footprint of transformer 208b and is coupled to third secondary winding 7011 by a center tap metal interconnect 7111. Third secondary winding 7010 includes coil portions 7028a and 7028b that terminate at, respectively, first secondary side terminal 7334b and second secondary side terminal 7336b. A pair of metal interconnects 7116 couples between receiver (RX) 717b of data circuit 216 and first secondary side terminals 7334b and second secondary side terminals 7336b. Symmetry/matching can be achieved by having the pair of metal interconnects 7116 overlapping with the branch portions of metal interconnect 7111 or being equal distance from the straight portion of metal interconnect 7111.

In at least one example, second primary winding 7007 and second secondary winding 7008 are electrically and galvanically isolated using an isolation material of package substrate 102, which forms a galvanic isolation barrier between two different power/data domains of data circuit 216 and data circuit 226. In at least one example, data circuit 216 is powered using a voltage supply and ground connection associated with a first power domain. In at least one example, data circuit 226 is powered using a different voltage supply and ground connection associated with a second power domain.

Using a mold compound as the isolation material of package substrate 102, instead of a laminate, allows for a smaller critical separation between second primary winding 7007 and second secondary winding 7008 while maintaining the same voltage insulation and allows for improved thermal performance of integrated isolation circuit 108.

Both transformers 208a and 208b can be formed in two metal layers. For example, as shown in FIG. 7A and FIG. 7B, second primary winding 7007, center tap metal interconnects 7101, metal interconnects 7103, third primary winding 7010, center tap metal interconnects 7112, and metal interconnects 7111 can be formed on a first metal layer (e.g., the top metal layer). Second secondary winding 7008, center tap metal interconnects 7102, metal interconnects 7114, third secondary winding 7011, and center tap metal interconnects 7111 can be formed on a second metal layer below the first metal layer. The two-layer configuration is achieved by trading off coupling between primary and secondary windings to achieve a layout symmetry of the primary and secondary windings that result in lower parasitic barrier capacitance and less electromagnetic radiation.

FIG. 7C is a schematic showing an isometric top zoomed-in view of a data transformer of packaged IC 7300 having the partially overlapping primary and secondary windings of the data transformers, in accordance with at least one example. Here, packaged IC 7300 is similar to packaged IC portion 7200 in feature and functionality, with each center tap metal interconnect having a straight portion, and symmetry/matching is achieved by having the pair of metal interconnects coupled between the primary/secondary side terminals and the data circuits to be of equal distance to the straight portion, as explained above.

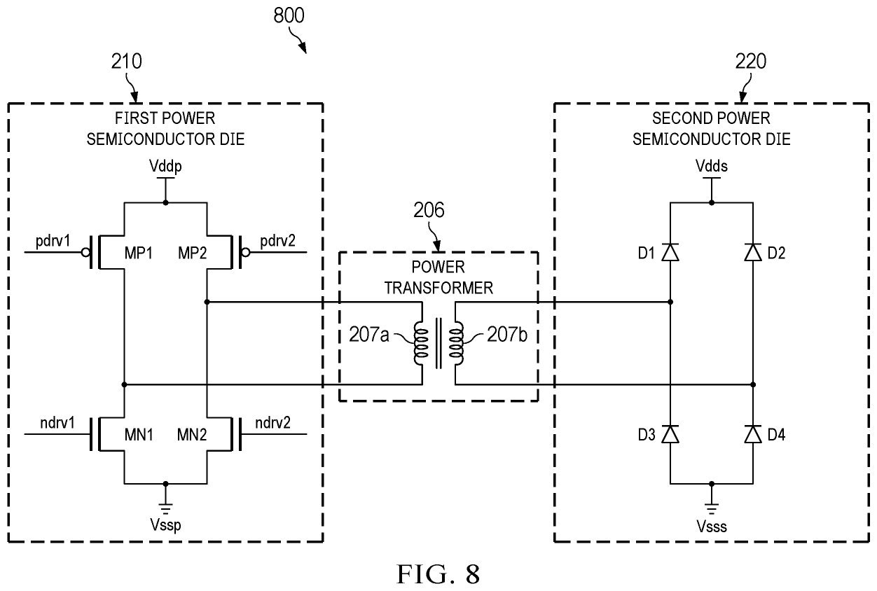

FIG. 8 is a schematic showing a DC-DC converter 800 formed on two semiconductor dies coupled by a power transformer, in accordance with at least one example. In at least one example, first semiconductor die 210 includes a first power circuit comprising p-type transistors (or FETs) MP1 and MP2 coupled to primary power supply Vddp, and n-type transistors MN1 and MN2 coupled for primary ground Vssp. Transistor MP1 is controllable by pdrv1, transistor MP2 is controllable by pdrv2, transistor MN1 is controllable by ndrv1, and transistor MN2 is controllable by ndrv2. Here, node names and signal names are interchangeably used. For example, pdrv1 may refer to node pdrv1 or signal pdrv1 depending on the context of the sentence. Transistors MP1 and MP2 are high-side bridges while transistors MN1 and MN2 are low-side bridges. High-side bridges are turned on and off by pdrv1 and pdrv2. In at least one example, data circuit 216 and/or 226 generate pdrv1 and pdrv2 signals based on a desired regulated output voltage and a reference voltage. Low-side bridges are turned on and off by ndrv1 and ndrv2. In at least one example, data circuit 216 and/or 226 generate ndrv1 and ndrv2 signals based on the desired regulated output voltage and the reference voltage. High-side bridges are coupled in series with low-side bridges, and coupled to primary winding 207a of transformer 206. As discussed herein, half of primary winding 207a is in first metal layer 420 of package substrate 102 while the other half of primary winding 207a is in second metal layer 430 of package substrate 102.

In at least one example, second semiconductor die 220 includes two sets of diodes that are coupled in parallel. These diodes include diode D1 and D2 coupled to secondary power supply Vdds, and diode D3 and D4 coupled to secondary ground Vsss and to diodes D1 and D2. The two sets of diodes are coupled to secondary winding 207b of power transformer 206. As discussed herein, half of secondary winding 207b is in first metal layer 420 of package substrate 102 while the other half of secondary winding 207b is in second metal layer 430 of package substrate 102. While DC-DC converter 800 is illustrated as one example, other examples of DC-DC converters can be employed that use power transformer 206 as an isolation circuit.

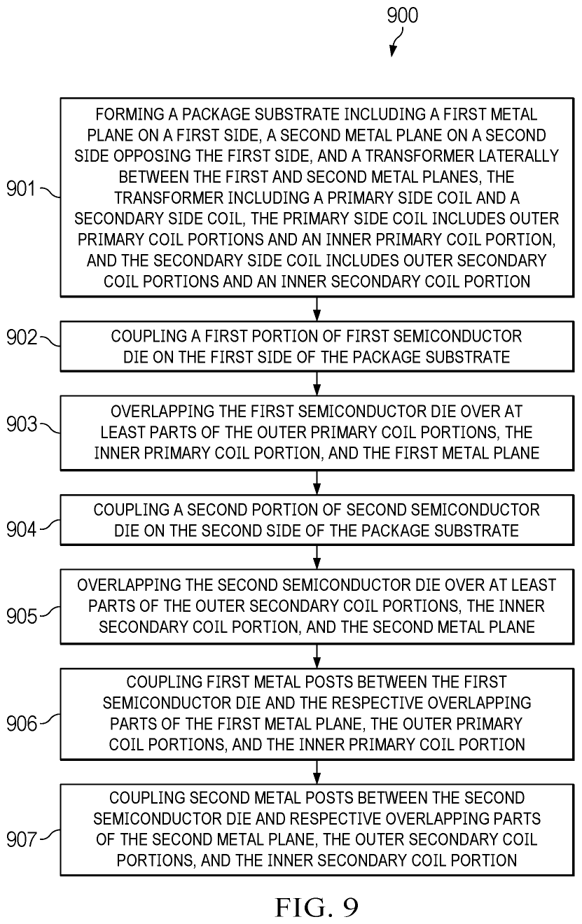

FIG. 9 is a flowchart 900 of a method of forming the packaged IC with three transformers, in accordance with at least one example. Various blocks of flowchart 900 are shown in a particular order. The order can be modified. For example, some blocks can be performed before others and some blocks may be performed in parallel. Flowchart 900 may be implemented using routable lead frame technology and may be performed as part of a process for manufacturing packaged ICs, such as packaged ICs of FIGS. 3, 4, 5A, 5B, 5C, 5D, 6, 7A, 7B, and 7C.

At block 901, package substrate 102 is formed including first metal plane 306a on the first side, second metal plane 306b on the second side opposing the first side, and a transformer 206 laterally between first metal plane 306a and second metal plane 306b. In at least one example, transformer 206 includes primary winding 207a and secondary winding 207b, where primary winding 207a includes outer primary coil portions (e.g., first outer primary coil portion 320a and second outer primary coil portion 320c) having first and second primary side terminals 321a/321b. In at least one example, primary winding 207a also includes inner primary coil portion 320f. In at least one example, secondary winding 207b includes outer secondary coil portions (e.g., first outer secondary coil portion 320b and second outer secondary coil portion 320a) having first and second secondary side terminals 321c/321d and an inner secondary coil portion 320e.

At block 902, first semiconductor die 210 is coupled on the first side of package substrate 102. At block 903, first semiconductor die 210 overlaps at least parts of the outer primary coil portions, inner primary coil portion 320f, and first metal plane 306a. At block 904, second semiconductor die 220 is coupled to the second side of package substrate 102. At block 905, second semiconductor die 220 is overlapped over at least parts of the outer secondary coil portions, inner secondary coil portion 320e, and second metal plane 306b. At block 906, a first subset of metal posts or pillars (e.g., 321a, 321b) are coupled between first semiconductor die 210 and the respective overlapping parts of first metal plane 306a, the primary side terminals, and inner primary coil portion 320f. At block 907, a second subset of metal posts or pillars (e.g., 303a, and 321d) are coupled between second semiconductor die 220 and respective overlapping parts of second metal plane 306b, secondary side terminals 321c/321d, and inner secondary coil portion 320e.

The following are additional examples provided in view of the above-described implementations. Here, one or more features of example, in isolation or in combination, can be combined with one or more features of one or more other examples to form further examples also falling within the scope of the disclosure. As such, one implementation can be combined with one or more other implementation without changing the scope of disclosure.

Example 1 is a packaged integrated circuit comprising a package substrate including a first metal plane on a first side, a second metal plane on a second side opposing the first side, and a transformer laterally between the first and second metal planes, the transformer including a primary winding and a secondary winding, the primary winding includes outer primary coil portions having first and second primary side terminals and an inner primary coil portion, and the secondary winding includes outer secondary coil portions having first and second secondary side terminals and an inner secondary coil portion; a first semiconductor die on the first side of the package substrate and overlapping at least parts of the outer primary coil portions, the inner primary coil portion, and the first metal plane; a second semiconductor die on the second side of the package substrate and overlapping at least parts of the outer secondary coil portions, the inner secondary coil portion, and the second metal plane; first metal posts coupled between the first semiconductor die and the respective overlapping parts of the first metal plane, the primary side terminals, and the inner primary coil portion; and second metal posts coupled between the second semiconductor die and respective overlapping parts of the second metal plane, the secondary side terminals, and the inner secondary coil portion.

Example 2 is the packaged integrated circuit according to any example discussed herein, in particular example 1, wherein: the first semiconductor die includes a first circuit; the second semiconductor die includes a second circuit; the outer primary coil portions include a first outer primary coil portion and a second outer primary coil portion, the first outer primary coil portion coupled to the first primary side terminal, the second outer primary coil portion coupled to the second primary side terminal, and a subset of the first metal posts is coupled between the first circuit and the first and second primary side terminals; and the outer secondary coil portions include a first outer secondary coil portion and a second outer secondary coil portion, the first outer secondary coil portion coupled to the first secondary side terminal, and the second outer secondary coil portion coupled to the second secondary side terminal, and a subset of the second metal posts is coupled between the second circuit and the first and second secondary side terminals.

Example 3 is the packaged integrated circuit according to any example discussed herein, in particular example 2, wherein the subset of the first metal posts is a first subset of the first metal posts, and the subset of the second metal posts is a first subset of the second metal posts; wherein the first semiconductor die includes a third circuit electrically isolated from the first circuit, and the second semiconductor die includes a fourth circuit electrically isolated from the second circuit; wherein a second subset of the first metal posts is coupled between the third circuit and the inner primary coil portion; and wherein a second subset of the second metal posts is coupled between the fourth circuit and the inner secondary coil portion.

Example 4 is the packaged integrated circuit according to any example discussed herein, in particular example 3, wherein the third circuit includes a first floating metal layer on a first semiconductor substrate of the first semiconductor substrate, the second semiconductor die includes a second floating metal layer on a second semiconductor substrate of the second semiconductor die.

Example 5 is the packaged integrated circuit according to any example discussed herein, in particular example 2, wherein the package substrate includes a first metal layer and a second metal layer, the second metal layer being below the first metal layer; wherein the first outer primary coil portion, the second outer primary coil portion, the inner primary coil portion, the first outer secondary coil portion, the second outer secondary coil portion, and the inner secondary coil portion are upper coil portions in the first metal layer; and wherein the second metal layer includes: a first primary lower coil portion coupled between the first outer primary coil portion and the inner primary coil portion, a second primary lower coil portion coupled between the inner primary coil portion and the second outer primary coil portion, a first secondary lower coil portion coupled between the first outer secondary coil portion and the inner secondary coil portion, a second secondary lower coil portion coupled between the inner secondary coil portion and the second outer secondary coil portion.

Example 6 is the packaged integrated circuit according to any example discussed herein, in particular example 5, wherein: the first primary lower coil portion overlaps the first and second secondary terminals and at least parts of the first and second outer secondary coil portions; the second primary lower coil portion overlaps at least a part of the inner primary coil portion; the first secondary lower coil portion overlaps the first and second primary terminals and at least parts of the first and second outer primary coil portions; and the second secondary lower coil portion overlaps at least a part of the inner secondary coil portion.

Example 7 is the packaged integrated circuit according to any example discussed herein, in particular example 6, wherein the first outer primary coil portion, the second outer primary coil portion, and the inner primary coil portion are at a point of symmetry with respect to, respectively, the first outer secondary coil portion, the second outer secondary coil portion, and the inner secondary coil portion; and wherein the first primary lower coil portion and the second primary lower coil portion are at the point of symmetry with respect to, respectively, the first secondary lower coil portion and the second secondary lower coil portion.

Example 8 is the packaged integrated circuit according to any example discussed herein, in particular example 1, wherein the transformer is a first transformer, and the package substrate further includes a second transformer.

Example 9 is the packaged integrated circuit according to any example discussed herein, in particular example 8, wherein the second transformer is within a footprint of the first transformer, the first semiconductor die coupled to a primary side of the second transformer, and the second semiconductor die coupled to a secondary side of the second transformer.

Example 10 is the packaged integrated circuit according to any example discussed herein, in particular example 8, wherein the primary winding is a first primary winding, the secondary winding is a first secondary winding, and the second transformer includes a second primary winding and a second secondary winding; wherein the second primary winding includes a first coil portion and a second coil portion coupled to a first center tap; and wherein the second secondary winding includes a third coil portion and a fourth coil portion coupled to a second center tap.

Example 11 is the packaged integrated circuit according to any example discussed herein, in particular example 10, wherein the package substrate includes a first metal layer and a second metal layer, the second metal layer being below the first metal layer; wherein the second transformer includes a third winding; wherein the first primary winding and the first secondary winding are in the first and second metal layers; and wherein the second primary winding and the second secondary winding are in the first metal layer, and the third winding is in the second metal layer.

Example 12 is the packaged integrated circuit according to any example discussed herein, in particular example 11, wherein each of the second primary winding, the second secondary winding, and the third winding includes a respective figure-of-8 coil.

Example 13 is the packaged integrated circuit according to any example discussed herein, in particular example 11, wherein the first and second center taps are within a footprint of the second transformer.

Example 14 is the packaged integrated circuit according to any example discussed herein, in particular example 11, wherein the third winding includes a fifth coil portion and a sixth coil portion, the first and third coil portions overlapping at least part of the fifth coil portion, and the second and fourth coil portions overlapping at least part of the sixth coil portion.

Example 15 is the packaged integrated circuit according to any example discussed herein, in particular example 10, wherein: the first and second center taps are outside a footprint of the second transformer; the package substrate includes a first metal layer and a second metal layer, the second metal layer being below the first metal layer; the second primary winding and the second secondary winding are in the first and second metal layers, respectively; the first metal layer also includes the second primary winding, a first metal interconnect coupled between the first center tap and the second primary winding, and a pair of second metal interconnects coupled between the second secondary winding and the second semiconductor die; and the second metal layer also includes the second secondary winding, a third metal interconnect coupled between the second center tap and the second secondary winding, and a pair of fourth metal interconnects coupled between the second primary winding and the first semiconductor die.

Example 16 is the packaged integrated circuit according to any example discussed herein, in particular example 15, wherein the first metal interconnect includes a first branch portion that overlaps with the pair of fourth metal interconnects; and wherein the third metal interconnect includes a second branch portion that overlaps with the pair of second metal interconnects.

Example 17 is the packaged integrated circuit according to any example discussed herein, in particular example 15, wherein the first metal interconnect includes a first straight portion that is of equal distance to each one of the pair of fourth metal interconnects; and wherein the third metal interconnect includes a second straight portion that is of equal distance to each one of the pair of second metal interconnects.

Example 18 is the packaged integrated circuit according to any example discussed herein, in particular example 1, wherein the first and second semiconductor dies being mounted on a first surface of the package substrate; wherein the package substrate further includes first and second metal pads on a second surface of the package substrate opposing the first surface, the first semiconductor die coupled to at least some of the first metal pads, and the second semiconductor die coupled to at least some of the second metal pads.

Example 19 is the packaged integrated circuit according to any example discussed herein, in particular example 18, wherein the first metal pads are on the first side of the package substrate, the second metal pads are on the second side of the package substrate.

Example 20 is the packaged integrated circuit according to any example discussed herein, in particular example 1, wherein the package substrate is part of a routable lead frame.

Example 21 is a packaged integrated circuit comprising: a package substrate including a first transformer and a second transformer, the first transformer having first primary side terminals and first secondary side terminals, the second transformer having second primary side terminals and second secondary side terminals, in which the first primary side terminals, the first secondary side terminals, the second primary side terminals, and the second secondary side terminals are on a metal layer of the package substrate; a first semiconductor die coupled to the first primary side terminals and the second primary side terminals; and a second semiconductor die and coupled to the first secondary side terminals and the second secondary side terminals.

Example 22 is the packaged integrated circuit according to any example discussed herein, in particular example 21, wherein the first transformer including a first primary winding and a first secondary winding, the first primary winding includes outer primary coil portions having the first primary side terminals and an inner primary coil portion, and the first secondary winding includes outer secondary coil portions having the first secondary side terminals and an inner secondary coil portion.

Example 23 is the packaged integrated circuit according to any example discussed herein, in particular example 22, wherein the metal layer is a first metal layer, and the package substrate includes a second metal layer below the first metal layer; wherein the outer primary coil portions include a first outer primary coil portion and a second outer primary coil portion; wherein the outer secondary coil portions include a first outer secondary coil portion and a second outer secondary coil portion; wherein the first outer primary coil portion, the second outer primary coil portion, the inner primary coil portion, the first outer secondary coil portion, the second outer secondary coil portion, and the inner secondary coil portion are upper coil portions in the first metal layer; and wherein the second metal layer includes: a first primary lower coil portion coupled between the first outer primary coil portion and the inner primary coil portion, a second primary lower coil portion coupled between the inner primary coil portion and the second outer primary coil portion, a first secondary lower coil portion coupled between the first outer secondary coil portion and the inner secondary coil portion, a second secondary lower coil portion coupled between the inner secondary coil portion and the second outer secondary coil portion.

Example 24 is the packaged integrated circuit according to any example discussed herein, in particular example 23, wherein: the first primary lower coil portion overlaps the first secondary side terminals and at least parts of the first and second outer secondary coil portions; the second primary lower coil portion overlaps at least a part of the inner primary coil portion; the first secondary lower coil portion overlaps the first primary side terminals and at least parts of the first and second outer primary coil portions; and the second secondary lower coil portion overlaps at least a part of the inner secondary coil portion.

Example 25 is the packaged integrated circuit according to any example discussed herein, in particular example 24, wherein the first outer primary coil portion, the second outer primary coil portion, and the inner primary coil portion are at a point of symmetry with respect to, respectively, the first outer secondary coil portion, the second outer secondary coil portion, and the inner secondary coil portion; and wherein the first primary lower coil portion and the second primary lower coil portion are at the point of symmetry with respect to, respectively, the first secondary lower coil portion and the second secondary lower coil portion.

Example 26 is the packaged integrated circuit according to any example discussed herein, in particular example 22, wherein the second transformer includes a second primary winding and a second secondary winding; wherein the second primary winding includes a first coil portion and a second coil portion coupled to a first center tap; and wherein the second secondary winding includes a third coil portion and a fourth coil portion coupled to a second center tap.

Example 27 is the packaged integrated circuit according to any example discussed herein, in particular example 26, wherein the second transformer includes a third winding; wherein the second primary winding and the second secondary winding are in the first metal layer, and the third winding is in the second metal layer.

Example 28 is the packaged integrated circuit according to any example discussed herein, in particular example 27, wherein each of the second primary winding, the second secondary winding, and the third winding includes a respective figure-of-8 coil.

Example 29 is the packaged integrated circuit according to any example discussed herein, in particular example 27, wherein the first and second center taps are within a footprint of the second transformer.

Example 30 is the packaged integrated circuit according to any example discussed herein, in particular example 27, wherein the third coil includes a fifth coil portion and a sixth coil portion, the first and third coil portions overlapping at least part of the fifth coil portion, the second and fourth coil portions overlapping at least part of the sixth coil portion.

Example 31 is the packaged integrated circuit according to any example discussed herein, in particular example 26, wherein: the first and second center taps are outside a footprint of the second transformer; the first metal layer also includes the second primary winding, a first metal interconnect coupled between the first center tap and the second primary winding, and a pair of second metal interconnects coupled between the second secondary winding and the second semiconductor die; and the second metal layer also includes the second secondary winding, a third metal interconnect coupled between the second center tap and the second secondary winding, and a pair of fourth metal interconnects coupled between the second primary winding and the first semiconductor die.

Example 32 is the packaged integrated circuit according to any example discussed herein, in particular example 31, wherein the first metal interconnect includes a first branch portion that overlaps with the pair of fourth metal interconnects; and wherein the third metal interconnect includes a second branch portion that overlaps with the pair of second metal interconnects.

Example 33 is the packaged integrated circuit according to any example discussed herein, in particular example 31, wherein the first metal interconnect includes a first straight portion that is of equal distance to each one of the pair of fourth metal interconnects; and wherein the third metal interconnect includes a second straight portion that is of equal distance to each one of the pair of second metal interconnects.

Example 34 is the packaged integrated circuit according to any example discussed herein, in particular example 22, wherein the second transformer is within a footprint of the first transformer.

Example 35 is the packaged integrated circuit according to any example discussed herein, in particular example 22, wherein each of the first and second semiconductor dies partially overlap with at least one of the first or second transformers.

Example 36 is the packaged integrated circuit according to any example discussed herein, in particular example 21, wherein the package substrate includes a first metal plane on a first side, a second metal plane on a second side opposing the first side, wherein the first transformer and the second transformer are laterally between the first and second metal planes.

Example 37 is the packaged integrated circuit according to any example discussed herein, in particular example 21, wherein the first semiconductor die includes a first floating metal layer on a first semiconductor substrate of the first semiconductor substrate, the second semiconductor die includes a second floating metal layer on a second semiconductor substrate of the second semiconductor die.

Example 38 is the packaged integrated circuit according to any example discussed herein, in particular example 37, wherein the first primary side terminals couple to the first floating metal layer via a first set of pillars, wherein the first secondary side terminals are coupled to the second floating metal layer via a second set of pillars.

Example 39 is the packaged integrated circuit according to any example discussed herein, in particular example 21, wherein the first and second semiconductor dies being mounted on a first surface of the package substrate; wherein the package substrate further includes first and second metal pads on a second surface of the package substrate opposing the first surface, the first semiconductor die coupled to at least some of the first metal pads, and the second semiconductor die coupled to at least some of the second metal pads.

Example 40 is the packaged integrated circuit according to any example discussed herein, in particular example 39, wherein the first metal pads are on the first side of the package substrate, the second metal pads are on the second side of the package substrate.

Example 41 is the packaged integrated circuit according to any example discussed herein, in particular example 21, wherein the package substrate is part of a routable lead frame.

Example 42 is a method comprising: forming a package substrate including a first metal plane on a first side, a second metal plane on a second side opposing the first side, and a transformer laterally between the first and second metal planes, the transformer including a primary winding and a secondary winding, the primary winding includes outer primary coil portions having first and second primary side terminals and an inner primary coil portion, and the secondary winding includes outer secondary coil portions having first and second secondary side terminals and an inner secondary coil portion; coupling a first semiconductor die on the first side of the package substrate; overlapping the first semiconductor die over at least parts of the outer primary coil portions, the inner primary coil portion, and the first metal plane; coupling a second semiconductor die on the second side of the package substrate; overlapping the second semiconductor die over at least parts of the outer secondary coil portions, the inner secondary coil portion, and the second metal plane; coupling first metal posts between the first semiconductor die and the respective overlapping parts of the first metal plane, the primary side terminals, and the inner primary coil portion; and coupling second metal posts between the second semiconductor die and respective overlapping parts of the second metal plane, the secondary side terminals, and the inner secondary coil portion.

Example 43 is a method comprising: forming a package substrate including a first metal plane on a first side, a second metal plane on a second side opposing the first side, and a transformer laterally between the first and second metal planes, the transformer including a primary side coil and a secondary side coil, the primary side coil includes outer primary coil portions and an inner primary coil portion, and the secondary side coil includes outer secondary coil portions and an inner secondary coil portion; coupling a first portion of first semiconductor die on the first side of the package substrate; overlapping the first semiconductor die over at least parts of the outer primary coil portions, the inner primary coil portion, and the first metal plane; coupling a second portion of second semiconductor die on the second side of the package substrate; overlapping the second semiconductor die over at least parts of the outer secondary coil portions, the inner secondary coil portion, and the second metal plane; coupling first metal posts between the first semiconductor die and the respective overlapping parts of the first metal plane, the outer primary coil portions, and the inner primary coil portion; and coupling second metal posts between the second semiconductor die and respective overlapping parts of the second metal plane, the outer secondary coil portions, and the inner secondary coil portion.

Example 44 is a packaged integrated circuit comprising: a package substrate including a transformer having a primary coil and a secondary coil; a first semiconductor die on the package substrate and partially overlapping the primary coil, wherein the first semiconductor die includes a first metal plane which is floating; a set of pillars coupled to the primary coil and the first metal plane; and a second semiconductor die on the package substrate and partially overlapping the secondary coil, wherein the first semiconductor die and the second semiconductor die are symmetrically arranged relative to a center of the transformer.

Example 45 is the packaged integrated circuit according to any example discussed herein, in particular example 44, wherein the second semiconductor die includes a second metal plane which is floating, wherein the packaged integrated circuit further includes a second set of pillars coupled to the secondary coil and the second metal plane.

Example 46 is the packaged integrated circuit according to any example discussed herein, in particular example 45, wherein the first metal plane and the second metal plane are configured to conduct heat away from the package substrate.

Example 47 is the packaged integrated circuit according to any example discussed herein, in particular example 46, wherein the primary coil includes a first portion in a first metal layer, the first portion symmetrically arranged relative to the center of the transformer, and a second portion in a second metal layer separate from the first metal layer, the second portion symmetrically arranged relative to the center, the first portion coupled to the second portion through a first set of vias.

Example 48 is the packaged integrated circuit according to any example discussed herein, in particular example 47, wherein the secondary coil includes a third portion in the first metal layer, the third portion symmetrically arranged relative to the center of first transformer, and a fourth portion in the second metal layer, the fourth portion symmetrically arranged relative to the center, the third portion coupled to the fourth portion through a second set of vias.

Example 49 is the packaged integrated circuit according to any example discussed herein, in particular example 48, wherein the transformer is a first transformer, wherein the package substrate further includes a second transformer having a first coil arranged in a figure-of-8 configuration on the first metal layer, wherein the first semiconductor die overlaps a portion of the first coil.

Example 50 is the packaged integrated circuit according to any example discussed herein, in particular example 49, wherein the first coil includes a first contact centered in a first sub-coil of the first coil, a second contact centered in a second sub-coil of the first coil, and a third contact between the first contact and the second contact, wherein the third contact is coupled to a ground rail, wherein the first contact, the second contact, and the third contact are coupled to the first semiconductor die.

Example 51 is the packaged integrated circuit according to any example discussed herein, in particular example 50, wherein the second transformer includes a second coil arranged in a figure-of-8 configuration on the first metal layer, wherein the second semiconductor die overlaps a portion of the second coil.

Example 52 is the packaged integrated circuit according to any example discussed herein, in particular example 51, wherein the first coil and the second coil are symmetrically arranged between the first portion of the primary coil and the third portion of the secondary coil.

Example 53 is the packaged integrated circuit according to any example discussed herein, in particular example 51, wherein the second coil includes a first contact centered in a first sub-coil of the second coil, a second contact centered in a second sub-coil of the second coil, and a third contact between the first contact and the second contact of the second coil, wherein the third contact of the second coil is coupled to a ground rail, wherein the first contact, the second contact, and the third contact of the second coil are coupled to the second semiconductor die.

Example 54 is the packaged integrated circuit according to any example discussed herein, in particular example 53, wherein the package substrate further includes a third coil in the second metal layer, wherein the third coil is arranged in a figure-of-8 configuration, and wherein portions of the third coil overlap the first coil and the second coil.

Example 55 is the packaged integrated circuit according to any example discussed herein, in particular example 54, wherein the third coil is coupled to the first coil or the second coil through one or more vias.

Example 56 is the packaged integrated circuit according to any example discussed herein, in particular example 55, wherein the first semiconductor die includes a first power integrated circuit and a first data integrated circuit, wherein the second semiconductor die includes a second power integrated circuit and a second data integrated circuit.

Example 57 is the packaged integrated circuit according to any example discussed herein, in particular example 56, wherein the first power integrated circuit, the second power integrated circuit, the primary coil, and the secondary coil are part of a DC-DC converter.

Example 58 is the packaged integrated circuit according to any example discussed herein, in particular example 56, wherein the first data integrated circuit, the first coil and a portion of the second coil are part of a receiver, wherein the second data integrated circuit, the second coil and a portion of the second coil are part of a transmitter.

Example 59 is the packaged integrated circuit according to any example discussed herein, in particular example 44, wherein the primary coil and the secondary coil are part of a power transformer.

Example 60 is the packaged integrated circuit according to any example discussed herein, in particular example 44, wherein the first semiconductor die and the second semiconductor die are flip-chip dies.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In the description and in the claims, the terms “including” and “having” and variants thereof are intended to be inclusive in a manner similar to the term “comprising” unless otherwise noted. In addition, the terms “couple”, “coupled” or “couples” means an indirect or direct electrical or mechanical connection.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

What is claimed is:

1. A packaged integrated circuit comprising:
a package substrate including a first metal plane on a first side, a second metal plane on a second side opposing the first side, and a transformer laterally between the first and second metal planes, the transformer including a primary winding and a secondary winding, the primary winding includes outer primary coil portions having first and second primary side terminals and an inner primary coil portion, and the secondary winding includes outer secondary coil portions having first and second secondary side terminals and an inner secondary coil portion;
a first semiconductor die on the first side of the package substrate and overlapping at least parts of the outer primary coil portions, the inner primary coil portion, and the first metal plane;
a second semiconductor die on the second side of the package substrate and overlapping at least parts of the outer secondary coil portions, the inner secondary coil portion, and the second metal plane;
first metal posts coupled between the first semiconductor die and the respective overlapping parts of the first metal plane, the primary side terminals, and the inner primary coil portion; and
second metal posts coupled between the second semiconductor die and respective overlapping parts of the second metal plane, the secondary side terminals, and the inner secondary coil portion.

2. The packaged integrated circuit of claim 1, wherein:
the first semiconductor die includes a first circuit;
the second semiconductor die includes a second circuit;
the outer primary coil portions include a first outer primary coil portion and a second outer primary coil portion, the first outer primary coil portion coupled to the first primary side terminal, the second outer primary coil portion coupled to the second primary side terminal, and a subset of the first metal posts is coupled between the first circuit and the first and second primary side terminals; and
the outer secondary coil portions include a first outer secondary coil portion and a second outer secondary coil portion, the first outer secondary coil portion coupled to the first secondary side terminal, and the second outer secondary coil portion coupled to the second secondary side terminal, and a subset of the second metal posts is coupled between the second circuit and the first and second secondary side terminals.

3. The packaged integrated circuit of claim 2, wherein the subset of the first metal posts is a first subset of the first metal posts, and the subset of the second metal posts is a first subset of the second metal posts;
wherein the first semiconductor die includes a third circuit electrically isolated from the first circuit, and the second semiconductor die includes a fourth circuit electrically isolated from the second circuit;
wherein a second subset of the first metal posts is coupled between the third circuit and the inner primary coil portion; and
wherein a second subset of the second metal posts is coupled between the fourth circuit and the inner secondary coil portion.

4. The packaged integrated circuit of claim 3, wherein the third circuit includes a first floating metal layer on a first semiconductor substrate of the first semiconductor substrate, the second semiconductor die includes a second floating metal layer on a second semiconductor substrate of the second semiconductor die.

5. The packaged integrated circuit of claim 2, wherein the package substrate includes a first metal layer and a second metal layer, the second metal layer being below the first metal layer;
wherein the first outer primary coil portion, the second outer primary coil portion, the inner primary coil portion, the first outer secondary coil portion, the second outer secondary coil portion, and the inner secondary coil portion are upper coil portions in the first metal layer; and
wherein the second metal layer includes:
a first primary lower coil portion coupled between the first outer primary coil portion and the inner primary coil portion,
a second primary lower coil portion coupled between the inner primary coil portion and the second outer primary coil portion,
a first secondary lower coil portion coupled between the first outer secondary coil portion and the inner secondary coil portion,
a second secondary lower coil portion coupled between the inner secondary coil portion and the second outer secondary coil portion.

6. The packaged integrated circuit of claim 5, wherein:
the first primary lower coil portion overlaps the first and second secondary terminals and at least parts of the first and second outer secondary coil portions;
the second primary lower coil portion overlaps at least a part of the inner primary coil portion;
the first secondary lower coil portion overlaps the first and second primary terminals and at least parts of the first and second outer primary coil portions; and
the second secondary lower coil portion overlaps at least a part of the inner secondary coil portion.

7. The packaged integrated circuit of claim 6, wherein the first outer primary coil portion, the second outer primary coil portion, and the inner primary coil portion are at a point symmetry with respect to, respectively, the first outer secondary coil portion, the second outer secondary coil portion, and the inner secondary coil portion; and
wherein the first primary lower coil portion and the second primary lower coil portion are at the point symmetry with respect to, respectively, the first secondary lower coil portion and the second secondary lower coil portion.

8. The packaged integrated circuit of claim 1, wherein the transformer is a first transformer, and the package substrate further includes a second transformer.

9. The packaged integrated circuit of claim 8, wherein the second transformer is within a footprint of the first transformer, the first semiconductor die coupled to a primary side of the second transformer, and the second semiconductor die coupled to a secondary side of the second transformer.

10. The packaged integrated circuit of claim 8, wherein the primary winding is a first primary winding, the secondary winding is a first secondary winding, and the second transformer includes a second primary winding and a second secondary winding;
wherein the second primary winding includes a first coil portion and a second coil portion coupled to a first center tap; and
wherein the second secondary winding includes a third coil portion and a fourth coil portion coupled to a second center tap.

11. The packaged integrated circuit of claim 10, wherein the package substrate includes a first metal layer and a second metal layer, the second metal layer being below the first metal layer;
wherein the second transformer includes a third winding;
wherein the first primary winding and the first secondary winding are in the first and second metal layers; and
wherein the second primary winding and the second secondary winding are in the first metal layer, and the third winding is in the second metal layer.

12. The packaged integrated circuit of claim 11, wherein each of the second primary winding, the second secondary winding, and the third winding includes a respective figure-of-8 coil.

13. The packaged integrated circuit of claim 11, wherein the first and second center taps are within a footprint of the second transformer.

14. The packaged integrated circuit of claim 11, wherein the third winding includes a fifth coil portion and a sixth coil portion, the first and third coil portions overlapping at least part of the fifth coil portion, the second and fourth coil portions overlapping at least part of the sixth coil portion.

15. The packaged integrated circuit of claim 10, wherein:
the first and second center taps are outside a footprint of the second transformer;
the package substrate includes a first metal layer and a second metal layer, the second metal layer being below the first metal layer;
the second primary winding and the second secondary winding are in the first and second metal layers, respectively;
the first metal layer also includes the second primary winding, a first metal interconnect coupled between the first center tap and the second primary winding, and a pair of second metal interconnects coupled between the second secondary winding and the second semiconductor die; and
the second metal layer also includes the second secondary winding, a third metal interconnect coupled between the second center tap and the second secondary winding, and a pair of fourth metal interconnects coupled between the second primary winding and the first semiconductor die.

16. The packaged integrated circuit of claim 15, wherein the first metal interconnect includes a first branch portion that overlaps with the pair of fourth metal interconnects; and
wherein the third metal interconnect includes a second branch portion that overlaps with the pair of second metal interconnects.

17. The packaged integrated circuit of claim 15, wherein the first metal interconnect includes a first straight portion that is of equal distance to each one of the pair of fourth metal interconnects; and
wherein the third metal interconnect includes a second straight portion that is of equal distance to each one of the pair of second metal interconnects.

18. The packaged integrated circuit of claim 1, wherein the first and second semiconductor dies being mounted on a first surface of the package substrate;
wherein the package substrate further includes first and second metal pads on a second surface of the package substrate opposing the first surface, the first semiconductor die is coupled to at least some of the first metal pads, and the second semiconductor die is coupled to at least some of the second metal pads.

19. The packaged integrated circuit of claim 18, wherein the first metal pads are on the first side of the package substrate, and the second metal pads are on the second side of the package substrate.

20. The packaged integrated circuit of claim 1, wherein the package substrate is part of a routable lead frame.

21. A packaged integrated circuit comprising:
a package substrate including a first transformer and a second transformer, the first transformer having first primary side terminals and first secondary side terminals, the second transformer having second primary side terminals and second secondary side terminals, in which the first primary side terminals, the first secondary side terminals, the second primary side terminals, and the second secondary side terminals are on a metal layer of the package substrate;
a first semiconductor die coupled to the first primary side terminals and the second primary side terminals; and
a second semiconductor die coupled to the first secondary side terminals and the second secondary side terminals.

22. The packaged integrated circuit of claim 21, wherein the first transformer includes a first primary winding and a first secondary winding, the first primary winding includes outer primary coil portions having the first primary side terminals and an inner primary coil portion, and the first secondary winding includes outer secondary coil portions having the first secondary side terminals and an inner secondary coil portion.

23. The packaged integrated circuit of claim 22, wherein the metal layer is a first metal layer, and the package substrate includes a second metal layer below the first metal layer;
wherein the outer primary coil portions include a first outer primary coil portion and a second outer primary coil portion;
wherein the outer secondary coil portions include a first outer secondary coil portion and a second outer secondary coil portion;
wherein the first outer primary coil portion, the second outer primary coil portion, the inner primary coil portion, the first outer secondary coil portion, the second outer secondary coil portion, and the inner secondary coil portion are upper coil portions in the first metal layer; and
wherein the second metal layer includes:
a first primary lower coil portion coupled between the first outer primary coil portion and the inner primary coil portion,
a second primary lower coil portion coupled between the inner primary coil portion and the second outer primary coil portion,
a first secondary lower coil portion coupled between the first outer secondary coil portion and the inner secondary coil portion,
a second secondary lower coil portion coupled between the inner secondary coil portion and the second outer secondary coil portion.

24. The packaged integrated circuit of claim 23, wherein:
the first primary lower coil portion overlaps the first secondary side terminals and at least parts of the first and second outer secondary coil portions;
the second primary lower coil portion overlaps at least a part of the inner primary coil portion;
the first secondary lower coil portion overlaps the first primary side terminals and at least parts of the first and second outer primary coil portions; and
the second secondary lower coil portion overlaps at least a part of the inner secondary coil portion.

25. The packaged integrated circuit of claim 24, wherein the first outer primary coil portion, the second outer primary coil portion, and the inner primary coil portion are at a point symmetry with respect to, respectively, the first outer secondary coil portion, the second outer secondary coil portion, and the inner secondary coil portion; and
wherein the first primary lower coil portion and the second primary lower coil portion are at the point symmetry with respect to, respectively, the first secondary lower coil portion and the second secondary lower coil portion.

26. The packaged integrated circuit of claim 22, wherein the second transformer includes a second primary winding and a second secondary winding;
wherein the second primary winding includes a first coil portion and a second coil portion coupled to a first center tap; and
wherein the second secondary winding includes a third coil portion and a fourth coil portion coupled to a second center tap.

27. The packaged integrated circuit of claim 26, wherein the second transformer includes a third winding;
wherein the second primary winding and the second secondary winding are in the first metal layer, and the third winding is in the second metal layer.

28. The packaged integrated circuit of claim 27, wherein each of the second primary winding, the second secondary winding, and the third winding includes a respective figure-of-8 coil.

29. The packaged integrated circuit of claim 27, wherein the first and second center taps are within a footprint of the second transformer.

30. The packaged integrated circuit of claim 27, wherein the third coil includes a fifth coil portion and a sixth coil portion, the first and third coil portions overlapping at least part of the fifth coil portion, the second and fourth coil portions overlapping at least part of the sixth coil portion.

31. The packaged integrated circuit of claim 26, wherein:
the first and second center taps are outside a footprint of the second transformer;
the first metal layer also includes the second primary winding, a first metal interconnect coupled between the first center tap and the second primary winding, and a pair of second metal interconnects coupled between the second secondary winding and the second semiconductor die; and
the second metal layer also includes the second secondary winding, a third metal interconnect coupled between the second center tap and the second secondary winding, and a pair of fourth metal interconnects coupled between the second primary winding and the first semiconductor die.

32. The packaged integrated circuit of claim 31, wherein the first metal interconnect includes a first branch portion that overlaps with the pair of fourth metal interconnects; and
wherein the third metal interconnect includes a second branch portion that overlaps with the pair of second metal interconnects.

33. The packaged integrated circuit of claim 31, wherein the first metal interconnect includes a first straight portion that is of equal distance to each one of the pair of fourth metal interconnects; and
wherein the third metal interconnect includes a second straight portion that is of equal distance to each one of the pair of second metal interconnects.

34. The packaged integrated circuit of claim 22, wherein the second transformer is within a footprint of the first transformer.

35. The packaged integrated circuit of claim 22, wherein each of the first and second semiconductor dies partially overlap with at least one of the first or second transformers.

36. The packaged integrated circuit of claim 21, wherein the package substrate includes a first metal plane on a first side, a second metal plane on a second side opposing the first side, wherein the first transformer and the second transformer are laterally between the first and second metal planes.

37. The packaged integrated circuit of claim 21, wherein the first semiconductor die includes a first floating metal layer on a first semiconductor substrate of the first semiconductor substrate, the second semiconductor die includes a second floating metal layer on a second semiconductor substrate of the second semiconductor die.

38. The packaged integrated circuit of claim 37, wherein the first primary side terminals couple to the first floating metal layer via a first set of pillars, wherein the first secondary side terminals are coupled to the second floating metal layer via a second set of pillars.

39. The packaged integrated circuit of claim 21, wherein the first and second semiconductor dies being mounted on a first surface of the package substrate;
wherein the package substrate further includes first and second metal pads on a second surface of the package substrate opposing the first surface, the first semiconductor die coupled to at least some of the first metal pads, and the second semiconductor die coupled to at least some of the second metal pads.

40. The packaged integrated circuit of claim 39, wherein the first metal pads are on the first side of the package substrate, and the second metal pads are on the second side of the package substrate.

41. The packaged integrated circuit of claim 21, wherein the package substrate is part of a routable lead frame.
